(19) United States
(12) Patent Application Publication
(10) Pub. No.: US 2018/0033798 A1
(43) Pub. Date: Feb. 1, 2018

(54) NON-VOLATILE MEMORY WITH REDUCED VARIATIONS IN GATE RESISTANCE

(71) Applicant: SANDISK TECHNOLOGIES LLC, Plano, TX (US)

(72) Inventors: Ashish Baraskar, Santa Clara, CA (US); Raghuveer S. Makala, Campbell, CA (US); Ching-Huang Lu, Fremont, CA (US); Yao-Sheng Lee, Tampa, FL (US); Jian Chen, San Jose, CA (US)

(73) Assignee: SANDISK TECHNOLOGIES LLC, Plano, TX (US)

(21) Appl. No.: 15/445,409

(22) Filed: Feb. 28, 2017

Related U.S. Application Data
(63) Continuation-in-part of application No. 15/221,269, filed on Jul. 27, 2016.

(51) Int. Cl. H01L 27/11582; H01L 21/768; H01L 21/28; H01L 23/532; H01L 27/11565; H01L 23/528; H01L 21/02

(52) U.S. Cl. CPC H01L 27/11582; H01L 23/528; H01L 21/768; H01L 21/02164; H01L 21/0217; H01L 23/53257; H01L 27/11565; H01L 21/28282

(57) ABSTRACT

A three-dimensional non-volatile memory comprises a plurality of word line layers arranged alternatingly with a plurality of dielectric layers in a stack over a substrate. Higher word lines are implemented to be thicker than lower word lines in order to reduce variation in resistance among word lines.

### BACKGROUND OF THE INVENTION

Semiconductor memory devices have become more popular for use in various electronic devices. For example, non-volatile semiconductor memory is used in cellular telephones, digital cameras, personal digital assistants, mobile computing devices, non-mobile computing devices, servers and other devices. Flash memory is among the most popular non-volatile semiconductor memories.

As with many types of electronic devices, users of semiconductor memory devices desire high performance.

### BRIEF DESCRIPTION OF THE DRAWINGS

FIG. 1 is a circuit diagram of an example of a NAND string.

FIG. 2 is a perspective view of a 3D stacked non-volatile memory device.

FIG. 3A depicts an embodiment of a block BLK0A of U-shaped NAND strings.

FIG. 3B depicts a cross-sectional view of a block of the 3D non-volatile memory device of FIG. 3A of SetA0 of NAND strings of FIG. 3A.

FIG. 4A depicts an embodiment of a block BLK0B of straight NAND strings.

FIG. 4B depicts a cross-sectional view of a block of the 3D non-volatile memory device of FIG. 4A having straight strings.

FIG. 4C depicts a cross-sectional view of a block of a 3D non-volatile memory device having straight strings.

FIG. 5A depicts a close-up view of the region 669 of the column C0 of FIG. 4C, showing a drain-side select transistor SGD0 and a memory cell MC6,0.

FIG. 5B depicts a cross-sectional view of the column C0 of FIG. 5A.

FIGS. 6A and 6B depict an alternative embodiment to that of FIGS. 5A and 5B.

FIG. 7 is a cross-sectional close-up view of a memory hole having a diameter that varies with a vertical distance from a substrate surface.

FIG. 8 is a graph depicting programming speed based on word line position.

FIG. 9 is a graph depicting programming speed based on word line gate length.

FIG. 10 is a cross-sectional view of a portion of a 3D stacked memory array having word lines with a gate length that varies with a vertical distance from a substrate surface in one embodiment.

FIG. 11 is a graph comparing the programming speed of a traditional memory device with a memory device having word line zones with different thicknesses.

FIG. 12 is a flowchart describing a process of a fabricating a memory device with variable word line thicknesses in one embodiment.

FIGS. 13A-13L are cross-sectional views depicting the results of the process of FIG. 12 in one embodiment.

FIG. 14A is a cross-sectional view of a portion of a 3D stacked memory array.

FIG. 14B is a top view of the structure of FIG. 14A.

FIG. 14C is a bottom view of the structure of FIG. 14A.

FIG. 15 is a cross-sectional view of a portion of a 3D stacked memory array having word lines with a gate length that varies based on vertical distance from a substrate surface.

FIG. 15A is a close-up of a portion of the structure of FIG. 15.

FIG. 16 is a cross-sectional view of a portion of a 3D stacked memory array having word lines with a gate length that varies based on vertical distance from a substrate surface.

FIG. 17 is a cross-sectional view of a portion of a 3D stacked memory array having word lines with a gate length that varies based on vertical distance from a substrate surface.

FIG. 17A depicts a portion of the structure of FIG. 17, indicating example thicknesses for word line layers and dielectric/insulator layers.

FIG. 17B depicts a portion of the structure of FIG. 17, indicating example thicknesses for word line layers and dielectric/insulator layers.

FIG. 18 is a cross-sectional view of a portion of a 3D stacked memory array having word lines with a gate length that varies based on vertical distance from a substrate surface.

FIG. 18A depicts a portion of the structure of FIG. 18, indicating example thicknesses for word line layers and dielectric/insulator layers.

FIG. 18B depicts a portion of the structure of FIG. 18, indicating example thicknesses for word line layers and dielectric/insulator layers.

FIG. 19 is a flow chart describing one example implementation of step 902 of FIG. 12.

FIG. 20 is a cross-sectional view depicting the results of one embodiment of the process of FIG. 19.

FIG. 21 is a flow chart describing one example implementation of step 902 of FIG. 12.

FIG. 22 is a cross-sectional view depicting the results of one embodiment of the process of FIG. 21.

FIG. 23 is a flow chart describing one example implementation of step 902 of FIG. 12.

FIG. 24 is a cross-sectional view depicting the results of one embodiment of the process of FIG. 23.

FIG. 25 is a flow chart describing one example implementation of step 902 of FIG. 12.

FIG. 26 is a cross-sectional view depicting the results of one embodiment of the process of FIG. 26.

FIG. 27 is a functional block diagram of a memory device that includes a monolithic three dimensional memory array in accordance with the disclosure herein.

### DETAILED DESCRIPTION

To achieve higher capacity, three dimensional memories are being introduced. Some three dimensional memories comprise a plurality of word line layers arranged alternatingly with a plurality of dielectric/insulator layers in a stack over a substrate and a plurality of memory holes extending vertically through the stack. To maintain high performance during read processes, it is best if the plurality of word line layers have similar resistances. Different device dimensions between components in a non-volatile memory array may result from the various fabrication processes used to complete a final device. These differences may arise naturally from the processes used in some cases. To reduce the effects of differences in device dimensions, non-volatile memories and related fabrication processes are provided that can reduce variations in resistance of the word lines.

One embodiment of a non-volatile memory system comprises a plurality of dielectric/insulator layers and a plurality of word line layers arranged alternatingly with the plurality of dielectric/insulator layers in a stack. The plurality of dielectric/insulator layers include a first dielectric/insulator layer having a first insulator thickness positioned below a second dielectric/insulator layer having a second insulator thickness. The first insulator thickness is larger than the second insulator thickness. The plurality of word line layers include a first word line layer having a first word line thickness positioned below a second word line layer having a first word line thickness. The first word line thickness is smaller than the second word line thickness.

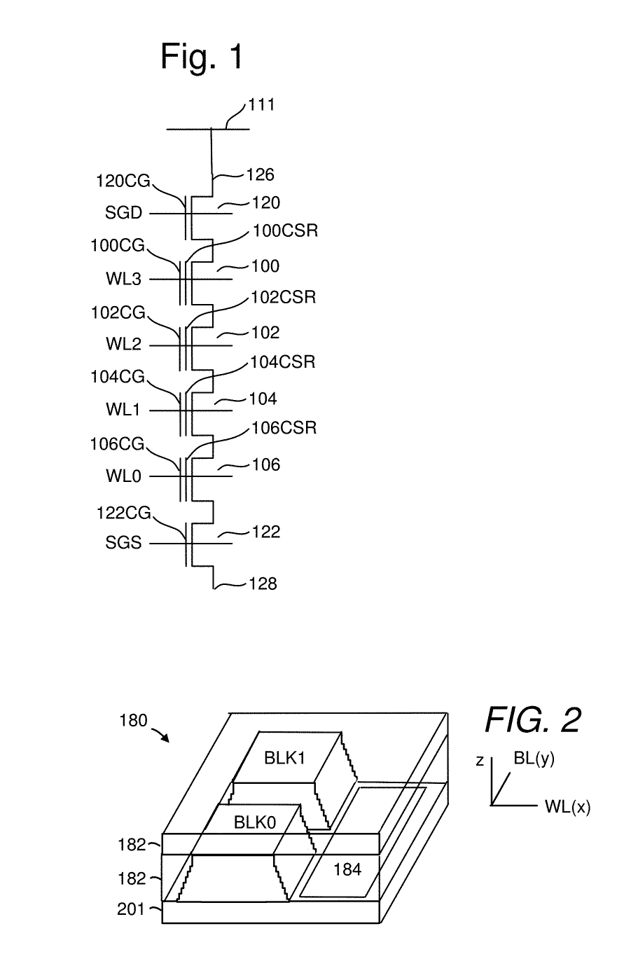

One example of a non-volatile storage system that can implement the technology described herein is a flash memory system that uses the NAND structure, which includes arranging multiple memory cell transistors in series, sandwiched between two select transistors. The memory cell transistors in series and the select transistors are referred to as a NAND string. FIG. 1 is a circuit representation of a NAND string. The NAND string depicted in FIG. 1 includes four memory cell transistors 100, 102, 104 and 106 in series and sandwiched between (drain side) select transistor 120 and (source side) select transistor 122.

Select transistor 120 connects the NAND string to a bit line 111. Select transistor 122 connects the NAND string to source line 128. Select transistor 120 is controlled by applying the appropriate voltages to select line SGD. The select line (SGD) is connected to a control gate terminal 120CG of the select transistor 120. Select transistor 122 is controlled by applying the appropriate voltages to select line SGS. The select line (SGS) is connected to a control gate terminal 122CG of the select transistor 122. Note that there may be more than one select transistor at each end of the NAND string, which work together as a switch to connect/disconnect the NAND string to and from the bit line and source line. For example, there may be multiple select transistors in series at each end of the NAND string.

Each of the memory cell transistors 100, 102, 104 and 106 has a control gate (CG) and a charge storage region (CSR). For example, memory cell transistor 100 has control gate 100CG charge storage region 1600CSR. Memory cell transistor 102 includes control gate 102CG and a charge storage region 102CSR. Memory cell transistor 104 includes control gate 104CG and charge storage region 104CSR. Memory cell transistor 106 includes a control gate 106CG and a charge storage region 106CSR. Control gate 100CG is connected to word line WL3, control gate 102CG is connected to word line WL2, control gate 104CG is connected to word line WL1, and control gate 106CG is connected to word line WL0.

Note that although FIG. 1 shows four memory cells in the NAND string, the use of four memory cells is only provided as an example. A NAND string can have fewer than four memory cells or more than four memory cells. The discussion herein is not limited to any particular number of memory cells in a NAND string. One embodiment uses NAND strings with some memory cells are used to store data and one or more of the memory cells are referred to as dummy memory cells because they do not store data.

A typical architecture for a flash memory system using a NAND structure will include many NAND strings. Each NAND string may be connected to the common source line by its source select transistor controlled by select line SGS and connected to its associated bit line by its drain select transistor controlled by select line SGD. Typically, each block may have a common source line. There may be a separate source line for each block. Bit lines may be shared with multiple NAND strings. The bit line may be connected to a sense amplifier.

The charge storage region (CSR) may utilize a non-conductive dielectric material to store charge in a non-volatile manner. The charge storage region may comprise one layer or several (e.g., three, four, or more) layers (or films) of different dielectric materials in one embodiment.

The memory cell transistor has a tunnel dielectric between the charge storage region and the channel of the memory cell transistor. Electrons can tunnel from the channel to the CSR during programming. The tunnel dielectric may include one or more different dielectric materials. In one embodiment, the tunnel dielectric comprises a single layer of silicon oxide (e.g., SiO₂). In one embodiment, the tunnel dielectric comprises a triple layer of silicon oxide (e.g., SiO₂), silicon nitride (e.g., Si₃N₄), and silicon oxide (e.g., SiO₂). The tunnel dielectric is not limited to these example materials.

The memory cell transistor has a control gate dielectric between the charge storage region and the control gate. The control gate dielectric may have one or more dielectric materials. The control gate dielectric is sometimes referred to as a “blocking dielectric” or “blocking oxide”. The control gate dielectric region comprises Al₂O₃ as a blocking layer, which blocks un-desirable tunneling of electrons from CSR to control gate or from control gate to CSR, in one embodiment. The control gate dielectric could instead of, or in addition to, the Al₂O₃ comprise a silicon oxide (e.g., SiO₂) layer. The control gate dielectric is not limited to these example materials.

The cell is programmed by injecting electrons from the cell channel (or NAND string channel) into the CSR, where they are trapped and stored in a limited region. This stored charge then changes the threshold voltage of the cell in a manner that is detectable. The cell may be erased by injecting holes from the channel into the CSR where they recombine with electrons, and thereby “cancel” or reduce the stored charge. Cells may be also erased by extracting electrons from the CSR, e.g., by applying an electric field making electrons tunnel from the CSR to the channel. Cells may be erased by both these mechanisms combined.

One example of a three dimensional (3D) stacked memory structure having strings of memory cells is sometimes referred to as a Bit Cost Scalable (BiCS) architecture. For example, a 3D NAND stacked memory device can be formed from an array of alternating conductor and insulator layers. In one technique, a memory hole is drilled in the layers to define many memory layers simultaneously. A NAND string is then formed by filling the memory hole with appropriate materials. A straight NAND string extends in one memory hole, while a pipe- or U-shaped NAND string (P-BiCS) includes a pair of vertical columns of memory cells which extend in two memory holes and which are joined by a pipe connection. The pipe connection may be made of undoped polysilicon. A dielectric and back gate may surround the pipe connection forming a back gate transistor to control conduction of the pipe connection. Control gates of the memory cells are provided by the conductor layers.

FIG. 2 is a perspective view of an example of a three dimensional (3D) stacked non-volatile memory device. The memory device 180 includes a substrate 201. On and above the substrate are example blocks BLK0 and BLK1 of memory cells (non-volatile storage elements). Also on substrate 201 is peripheral area 184 with support circuits for use by the blocks. Substrate 201 can also carry circuits under the blocks, along with one or more lower metal layers which are patterned in conductive paths to carry signals of the circuits. The blocks are formed in an intermediate region 182 of the memory device. In an upper region 182 of the memory device, one or more upper metal layers are patterned in conductive paths to carry signals of the circuits. Each block comprises a stacked area of memory cells, where alternating levels of the stack represent word lines. An x-y-z coordinate system is depicted, showing a y-direction (or bit line (BL) direction), an x-direction (or word line (WL) direction), as well as a z-direction. While two blocks are depicted as an example, additional blocks can be used, extending in the x- and/or y-directions.

In one example implementation, the length of the plane in the x-direction, represents a direction in which signal paths for word lines extend (a word line or SGD line direction), and the width of the plane in the y-direction, represents a direction in which signal paths for bit lines extend (a bit line direction). The z-direction represents a height of the memory device

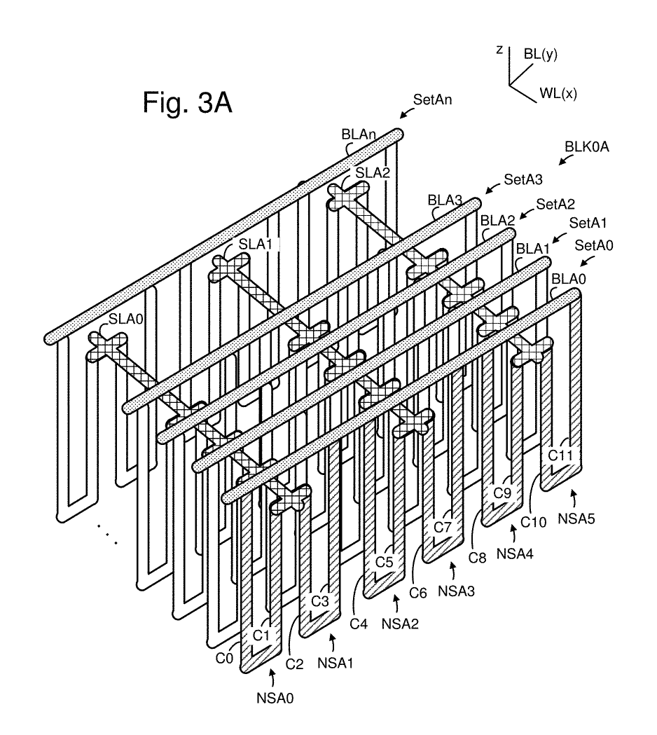

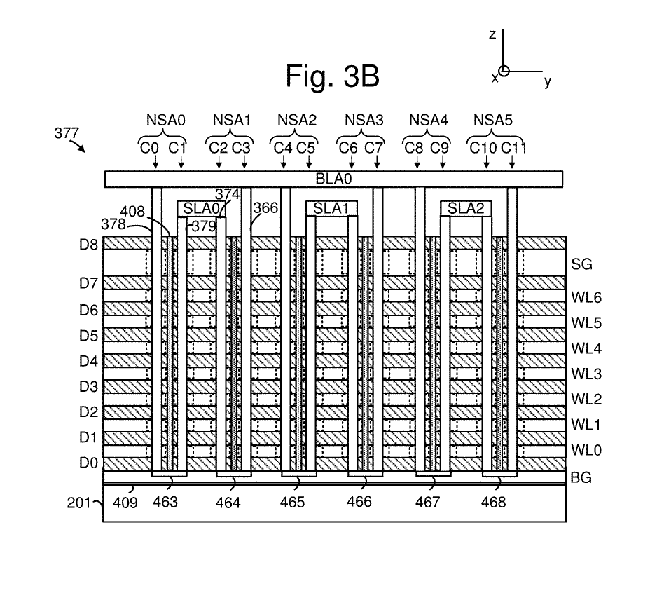

In one embodiment, NAND strings have a U-shape. In another embodiment, NAND strings have a straight shape. FIG. 3A depicts an embodiment of block BLK0 of FIG. 2 which includes U-shaped NAND strings. The block BLK0A includes U-shaped NAND strings arranged in sets (SetA0, . . . , SetAn, where there are n+1 sets of NAND strings in a block). Each set of NAND strings is associated with one bit line (BLA0, BLA1, BLA2, BLA3, . . . , BLAn). In one embodiment, each NAND string has a drain side select transistor that is able to connect/disconnect the NAND string from its bit line. The drain side select transistors in a set of NAND strings may be individually selectable, such that one NAND string in the set may be selected at a given time. In one approach, all NAND strings in a block which are associated with one bit line are in the same set. Each U-shaped NAND string thus has two columns of memory cells—a drain-side column and a source-side column. For example, SetA0 includes NAND strings NSA0 (having drain-side column C0 and source-side column C1), NSA1 (having drain-side column C3 and source-side column C2), NSA2 (having drain-side column C4 and source-side column C5), NSA3 (having drain-side column C7 and source-side column C6), NSA4 (having drain-side column C8 and source-side column C9) and NSA5 (having drain-side column C11 and source-side column C10). Source lines extend transversely to the bit lines and include SLA0, SLA1 and SLA2. The source lines join the source-side columns of adjacent NAND string in a set. For example, SLA0 joins C1 and C2, SLA1 joins C5 and C6 and SLA2 joins C9 and C10. In one approach, the source lines in a block are joined to one another and driven by one driver. The bit lines and the source lines are above the memory cell array in this example.

FIG. 3B depicts a cross-sectional view of a block of the 3D non-volatile memory device of FIG. 3A of SetA0 of NAND strings of FIG. 3A. Columns of memory cells C0 to C11 are depicted in the multi-layer stack. The stack 377 includes the substrate 201, an insulating film 409 on the substrate 201, and a back gate layer BG, which is a conductive layer, on the insulating film. A trench is provided in portions of the back gate below pairs of columns of memory cells of a U-shaped NAND string. Layers of materials which are provided in the columns to form the memory cells are also provided in the trenches, and the remaining space in the trenches is filled with a semiconductor material to provide connecting portions 463 to 468 which connect the columns. The back gate when properly biased, allows the back gate transistor to connect, through the pipe connection, thus connecting the two columns of each U-shaped NAND string. For example, NSA0 includes columns C0 and C1 and connecting portion 463. NSA0 has a drain end 378 and a source end 379. NSA1 includes columns C2 and C3 and connecting portion 464. NSA1 has a drain end 366 and a source end 374. NSA2 includes columns C4 and C5 and connecting portion 665. NSA3 includes columns C6 and C7 and connecting portion 466. NSA4 includes columns C8 and C9 and connecting portion 467. NSA5 includes columns C10 and C11 and connecting portion 468.

The source line SLA0 is connected to the source ends 379 and 374 of two adjacent memory strings NSA0 and NSA1, respectively, in the SetAO of memory strings. The source line SLA0 is also connected to other sets of memory strings which are behind NSA0 and NSA1 in the x direction. Recall that additional U-shaped NAND strings in the stack 377 extend behind the U-shaped NAND strings depicted in the cross-section, e.g., along the x-axis. The U-shaped NAND strings NSA0 to NSA5 are each in a different sub-block, but are in a common set of NAND strings (SetAO).

A slit portion 408 is also depicted as an example. In the cross-section, multiple slit portions are seen, where each slit portion is between the drain- and source-side columns of a U-shaped NAND string. Portions of the source lines SLA0, SLA1, SLA2 are also depicted. A portion of the bit line BLA0 is also depicted.

Short dashed lines depict memory cells (or memory cell transistors) and select transistors, as discussed further below. Thus, FIG. 3B shows strings (e.g., NAND strings) of non-volatile storage elements formed above the substrate 201 in multiple physical levels of a three-dimensional memory array. Each of the strings has an active area comprising a channel that extends vertically through the physical levels. Each string comprises non-volatile storage elements and a drain side select transistor in the SG layer.

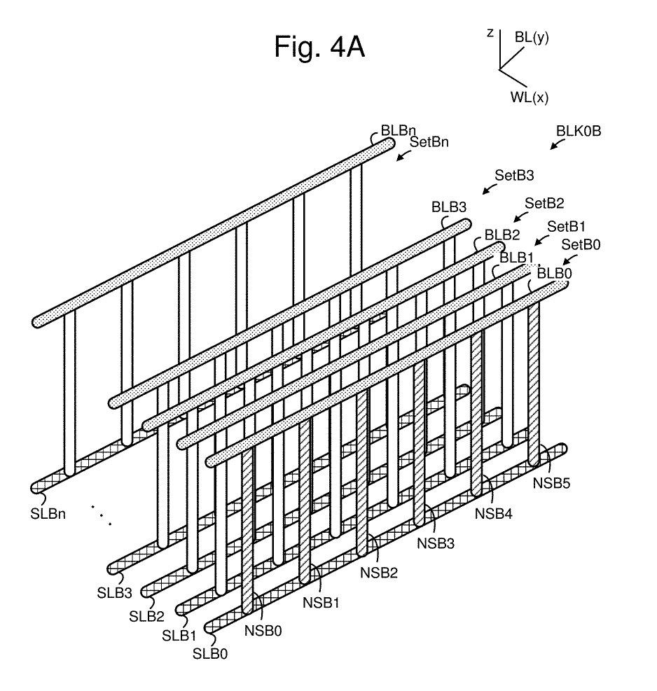

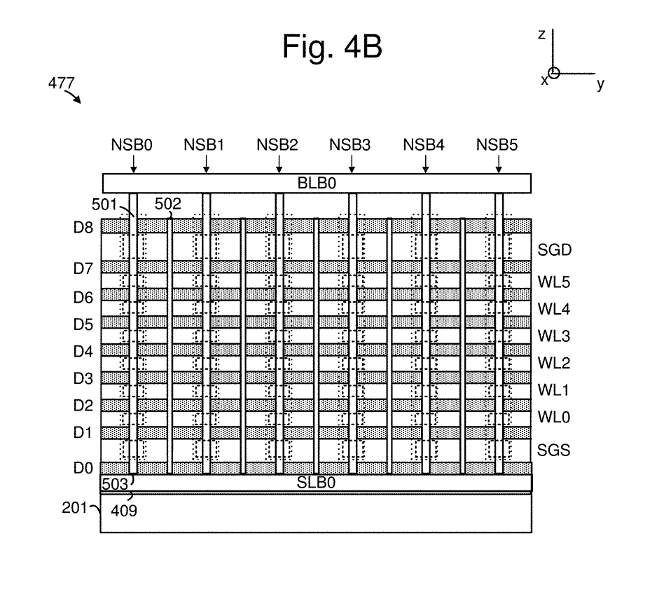

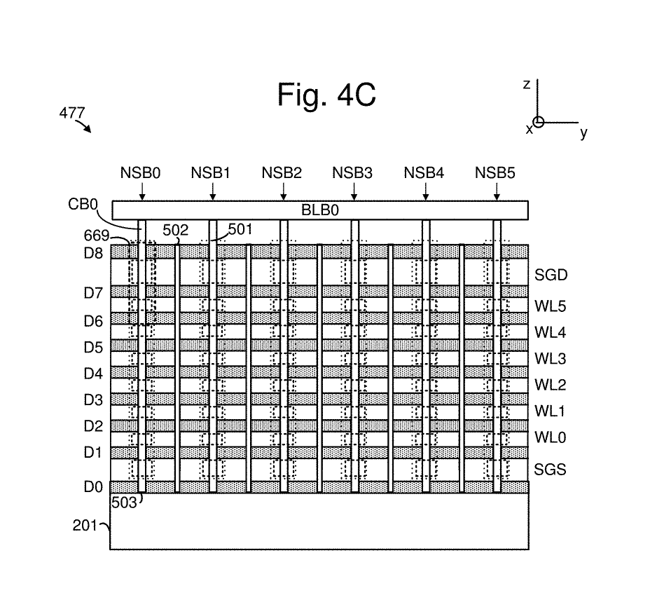

FIG. 4A depicts an embodiment of block BLK0 of FIG. 2 which includes straight NAND strings. The block BLK0B includes straight NAND strings arranged in sets (SetB0, SetB1, SetB2, SetB3, . . . , SetBn, where there are n+1 sets in a block). Each set of NAND strings is associated with one bit line (BLB0, BLB1, BLB2, BLB3, . . . , BLBn). In one approach, all NAND strings in a block which are associated with one bit line are in the same set. Each straight NAND string has one column of memory cells. For example, SetA0 includes NAND strings NSB0, NSB1, NSB2, NSB3, NSB4 and NSB5. Source lines extend parallel to the bit line and include SLB0, SLB1, SLB2, SLB3, . . . , SLBn. In one approach, the source lines in a block are joined to one another and driven by one driver. The bit lines are above the memory cell array and the source lines are below the memory cell array in this example.

FIG. 4B depicts a cross-sectional view of a block of the 3D non-volatile memory device of FIG. 4A having straight strings. The view is of a portion of setB0 of NAND strings of FIG. 4A. Columns of memory cells corresponding to NAND strings NSB0 to NSB5, respectively, are depicted in the multi-layer stack. The stack 477 includes a substrate 201, an insulating film 409 on the substrate, and a portion of a source line SLB0. Additional straight NAND strings in a sub-block may extend in front of and in back of the NAND strings depicted in the cross-section, e.g., along the x-axis. The NAND strings NSB0 to NSB5 may each be in a different sub-block, but are in a common set of NAND strings (SetB0). NSB0 has a source end 503 and a drain end 501. A slit 502 is also depicted with other slits. It is not required that there be a slit 502 between each pair of strings, as depicted. For example, slits could be used to separate blocks. Slits could be placed between several groups of strings within a block. In this case, a group of strings separated by slits within a block may be referred to as a “finger”. There may be several fingers within a block. A portion of the bit line BLB0 is also depicted. Dashed lines depict memory cells and select transistors, as discussed further below.

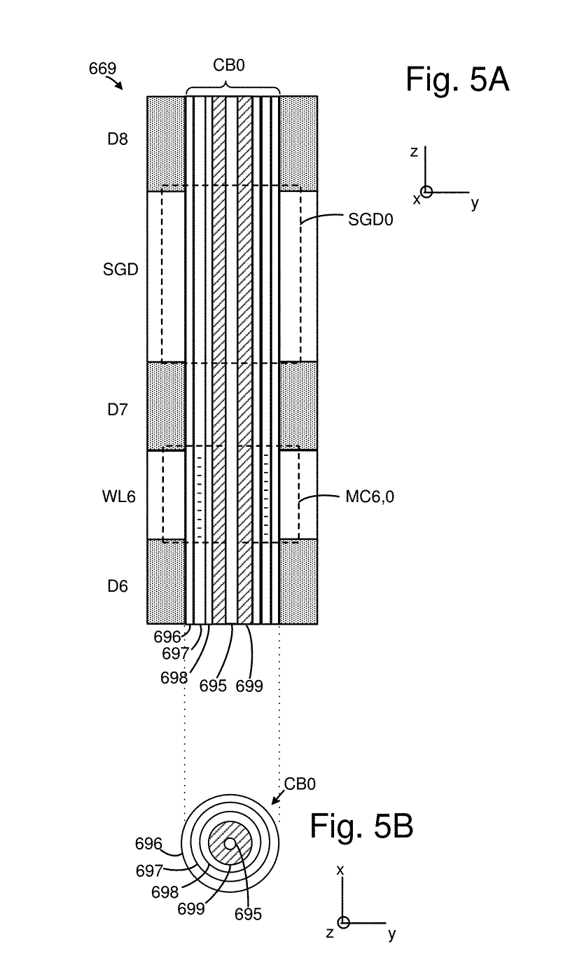

FIG. 4C depicts a cross-sectional view of a block of another embodiment of a 3D non-volatile memory device having straight strings. This embodiment differs from that of the embodiment of FIG. 4B in that the source end 503 of the NAND strings does not directly contact the source line. Instead, the source end 503 of the NAND string is in direct physical contact with the semiconductor substrate 201. The semiconductor substrate 201 may be silicon. The source line is not depicted in FIG. 4C. A region 669 of the stack that includes column CB0 is shown in greater detail in FIG. 5A.

FIG. 5A depicts a close-up view of region 669, which includes column CB0 of FIG. 4C, showing a drain-side select transistor SGD0 and a memory cell MC6,0 (also referred to as “memory cell transistor”). FIG. 5B depicts a cross-sectional view of the column CB0 of FIG. 5A. The region 669 shows portions of the dielectric layers D6 to D8 and the conductive layers WL6 and SGD.

Each column includes a number of regions, 695 696, 697, 698, 699. Region 696 is a control gate dielectric (also referred to as a “blocking oxide”). The portion of word line WL6 that is adjacent to region 696 serves as the control gate for memory cell MC6,0. Region 697 is the charge storage region (CSR). Region 698 is the tunnel dielectric region. Region 699 is the semiconductor channel. Region 695 is an optional core dielectric.

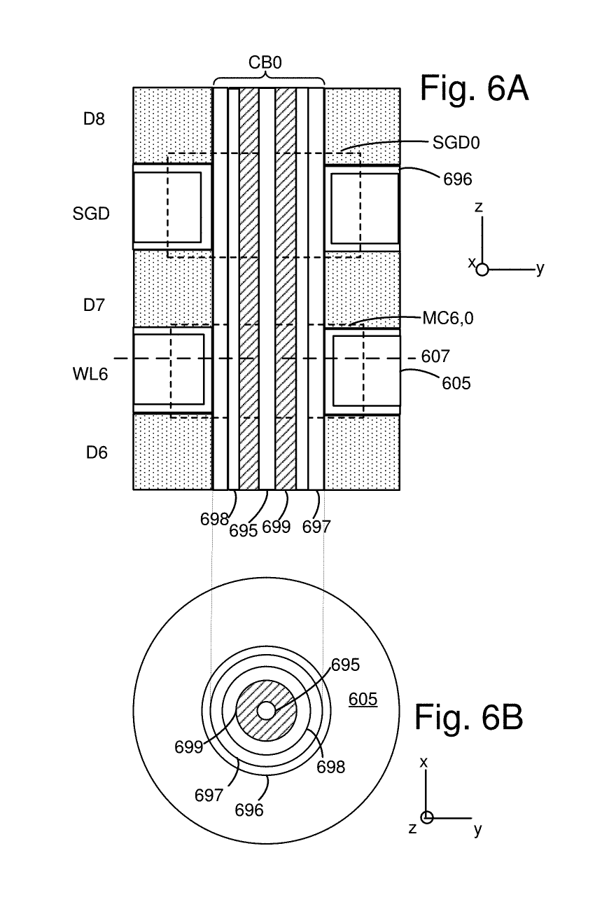

A variety of techniques could be used to form the regions, 695 696, 697, 698, 699. One technique is to drill memory holes into horizontal layers of some material and then fill those memory holes, resulting in a memory column that (in one embodiment) can be a NAND string. Note that the memory holes are not necessarily drilled into the horizontal material depicted in FIG. 5A. One option is to first have a sacrificial material instead of the conductive layers WL6 and SGD. After drilling the memory holes and filling the memory holes to form the column, the sacrificial material can be replaced with conductive material for WL6 and SGD. Some of the layers might be formed using atomic layer deposition. For example, a block oxide (or blocking layer) can be deposited on vertical sidewalls of the memory hole as layer 696, several dielectric layers can be deposited as layer 697, and a tunnel dielectric (or tunneling layer) can be deposited as layer 698. It is not required that all of these layers be formed in the column. An example is discussed below in FIG. 6A in which the blocking layer is not a part of the column.

The charge trapping region 697 comprises one or several layers of different materials in different example. The block oxide layer 696 and the tunnel dielectric layer 698 may each be formed from one or several layers of different dielectric materials. In one embodiment, the block oxide layer 696 comprises a layer of Al₂O₃ and a layer of SiO₂ (the Al₂O₃ layer is closer to the word line than the SiO₂, in one embodiment). In one embodiment, the tunnel dielectric layer 698 comprises a stack of oxide, nitride and oxide films. Additional memory cells are similarly formed throughout the columns.

When a memory cell such as depicted in FIG. 5A is programmed, electrons are stored in a portion of the charge trapping layer which is associated with the memory cell. For example, electrons are represented by “-” symbols in the charge trapping region 697 for MC6,0 in FIG. 5A. These electrons are drawn into the charge trapping region from the semiconductor channel 699, and through the tunnel dielectric 698. The threshold voltage of a memory cell is increased in proportion to the amount of stored charge.

During one embodiment of an erase operation, a voltage in the NAND channel may be raised due to GIDL, while a voltage of one or more selected word line layers floats. GIDL may occur due to high potential difference between bit line bias and bias applied on SGD to the control gate of the drain side transistor, and similarly, between source line bias and bias applied on SGS to the control gate of the source side transistor. The voltage of the one or more selected word line layers is then driven down sharply to a low level such as 0 V to create an electric field across the tunnel dielectric which may cause holes to be injected from the memory cell's body to the charge trapping region and recombine with electrons. Also, electrons can tunnel from the charge trapping region to the positively biased channel. One or both of these mechanisms may work to remove negative charge from the charge trapping region and result in a large Vth downshift toward an erase-verify level, Vv-erase. This process can be repeated in successive iterations until an erase-verify condition is met. For unselected word lines, the word lines may be floated but not driven down to a low level so that the electric field across the tunnel dielectric is relatively small, and no, or very little, hole tunneling will occur. If word lines are floated, they will be electrically coupled to the NAND channel. As a result their potential will rise resulting in low potential difference between NAND channel and respective word lines. Memory cells of the unselected word lines will experience little or no Vth downshift, and as a result, they will not be erased. Other techniques may be used to erase.

FIGS. 6A and 6B depict an alternative embodiment to that of FIGS. 5A and 5B. FIG. 6A shows similar layers D6, WL6, D7, SGD, and D8, as were depicted in FIG. 5A. A memory cell MC6,0 and a drain side select transistor SGD0, are shown. Note that in this embodiment, the column CB0 has charge trapping region 697, tunnel dielectric layer 698, and the semiconductor channel 699. However, in the embodiment of FIGS. 6A and 6B, the blocking layer 696 is located outside of the column CB0. The blocking layer 696 has a portion that is in direct contact with charge trapping region 697. The blocking layer 696 has an optional portion above and below the word line 605. This optional portion results from one embodiment of the fabrication process in which after forming the column, sacrificial material is removed where the word line and blocking layer are to be formed. Then, the blocking layer 696 is deposited, followed by depositing the word line 605. FIG. 6B shows a cross section of FIG. 6A along line 607.

Note that the size of the memory holes may impact the operating voltages due to what may be referred to as “the curvature effect”. The smaller the radius of the memory hole, the greater the curvature. Greater curvature may lead to higher electric fields. Thus, if the radius of the memory hole is increased, this may lead to lower electric fields. These lower electric fields may lead to the need for higher operating voltages. Therefore, if the radius of the memory hole is larger, higher operating voltages may be needed.

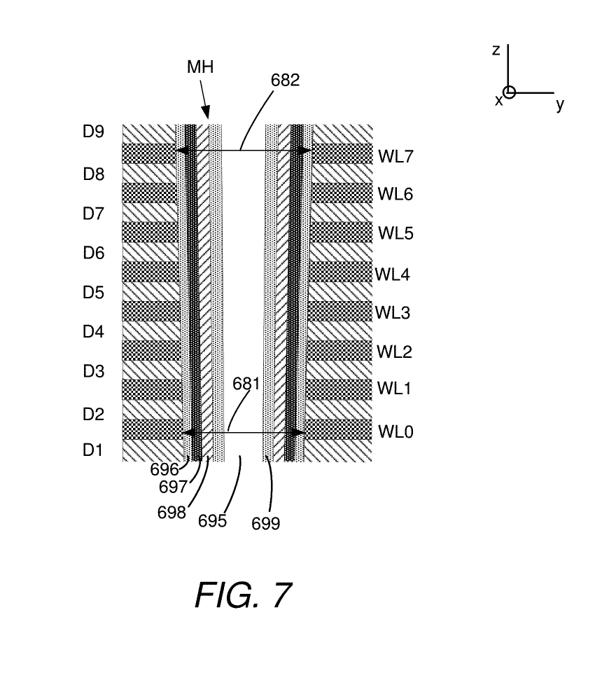

FIG. 7 is a cross-sectional view showing a more detailed view of a portion of a memory hole MH formed in a word line stack. Memory hole MH is formed through a stack including word line layers WL0-WL7 formed alternatingly with dielectric or insulating layers D0-D8. It is noted that a memory hole MH is considered to be present in a final device even though it is later filled with various materials as shown. The materials that fill in the memory hole are referred to as a memory column.

Memory hole MH (which includes the resulting memory column of materials formed therein) has a varying diameter which becomes progressively and gradually smaller from the top of the stack to the bottom of the stack. The memory hole is columnar and extends from at least a top word line layer (e.g., WL7) to a bottom word line layer (e.g., WL0). At a top region of the memory hole adjacent to word line WL7, the memory hole has a diameter labeled 682. At a bottom region of the memory hole adjacent to word line WL0, the memory hole has a diameter labeled 681. The diameter at the top is larger than the diameter at the bottom as a result of the fabrication of the memory hole. Due to the very high aspect ratio, the memory hole becomes narrower toward the bottom of the memory hole, becoming progressively smaller from the top to the bottom of the memory hole. It is noted that a slight widening may occur at some regions.

The non-uniformity of the memory hole causes the programming speed of the memory cells to vary based on their position in the memory hole. Where the diameter is smaller toward the bottom of the hole, the electric field across tunnel oxide 698 is stronger, so that the programming speed is higher. The smaller hole size concentrates the electric field resulting in stronger or faster programming. Thus, the memory cells adjacent to the word lines can be expected to have programming speeds that decrease progressively and gradually from the bottom (WL0) to the top (WL7) of the memory hole.

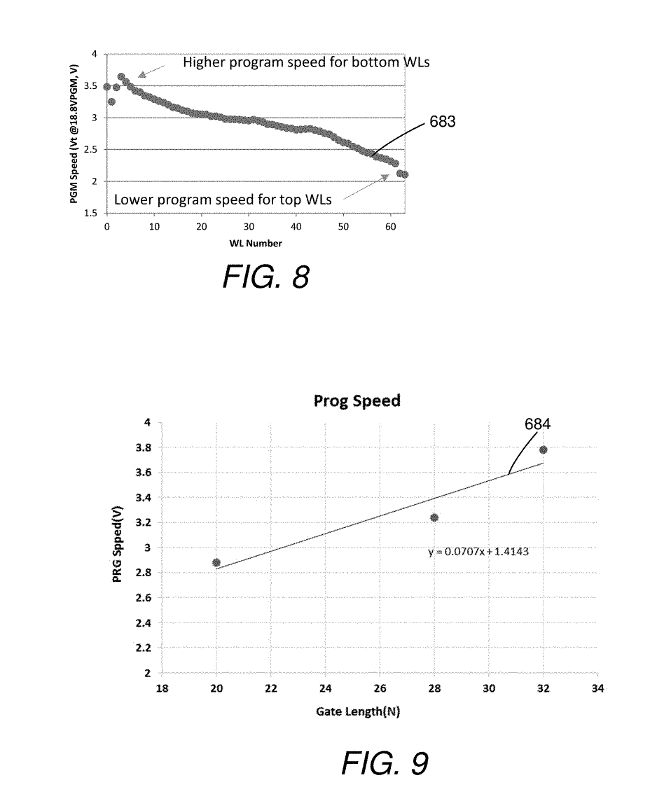

FIG. 8 is a graph illustrating the differences in programming speed that may result from differences in memory hole diameter in a NAND string having sixty four (64) lines. The programming speed, represented as the threshold voltage after application of a 18.8V programming pule, is shown along the y-axis and the word line number is shown along the x-axis. Line 683 illustrates that the programming speed gradually decreases from word line 0 to word line 63

The programming speed of a memory cell may also vary based on the gate length of the control gate or word line. Word lines with a longer gate length have a higher programming speed while word lines with a shorter gate length have a lower programming speed. FIG. 9 is a graph illustrating the effect of gate length on programming speed for memory cells. The programming speed as shown along the y-axis and the gate length is shown along the x-axis. Line 684 illustrates that the programming speed increases as the gate length is increased. The gate length in a stacked three dimensional structure is defined by the vertical thickness (relative to the substrate surface) of the word line layer.

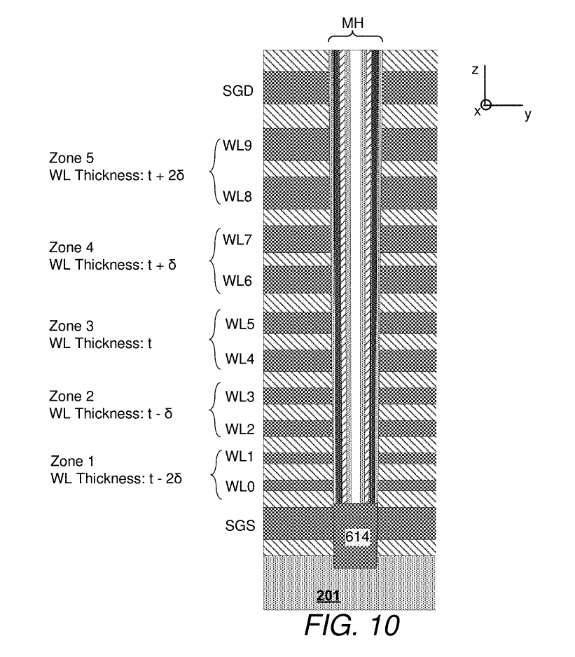

FIG. 10 is a cross-sectional view of a portion of a stacked three-dimensional memory array in accordance with one embodiment. The thickness of the word line layers is varied based on the diameter of the memory hole adjacent to the word line. In this example, the word lines are divided into zones 1-5 where each word line in a zone is formed with the same thickness. The thickness of the word lines in each zone varies such that the thickness for each word line increases from the bottom to the top of the memory hole. In this particular example, zone 3 is shown as having a nominal or target thickness t which may correspond to a desired operating condition, etc. of the device. Word lines WL4 and WL5 in zone 3 are formed with a thickness of t. Zone 2 includes word lines WL2 and WL3 and is formed immediately below zone 1. Word lines WL2 and WL3 are formed with a thickness of t−δ, where δ represents an offset from the target thickness t. Thus, word lines WL2 and WL3 have a thickness that is less than that of word lines WL4 and WL5. Zone 1 includes word lines WL0 and WL1 and is formed immediately below zone 2. Word lines WL0 and WL1 are formed with a thickness of t−2 δ. Thus, word lines have a thickness that is less the thickness of word lines WL2-WL5. In one embodiment, δ is equal to 3.5 nm however, the actual value of δ can vary by implementation.

Zone 4 includes word lines WL6 and WL7 which are formed immediately above the word lines in zone 3. Word lines WL6 and WL7 are formed with a thickness t+δ. Thus, word lines WL6 and WL7 have a thickness and gate length that is larger than that of the underlying word lines WL0-WL5. Zone 5 includes word lines WL8 and WL9 which are formed immediately above the word lines in zone 4. Word lines WL8 and WL9 are formed with a thickness t+2δ. Thus, word lines WL8 and WL9 have a thickness and gate length that is larger than that of the underlying word lines WL0-WL7.

The increase in word line thickness corresponds with the increase in memory hole diameter. In this fashion, the programming speed can be controlled to reduce variances along the memory cells of a NAND string. The thickness of a word line is smaller to correspond with a smaller memory hole diameter where the electric field during programming is strong. The thickness of a word line is larger to correspond with a larger diameter where the electric field during programming is weaker. Accordingly, the programming speed can controlled to be more consistent and predictable despite variances in the memory hole dimensions.

Many variations of word line thicknesses to define word line gate lengths may be used. For example, the value of δ does not have to be the same for all zones. For example, the thickness variation between zone 5 and zone 4 may be different than the thickness variation between zone 4 and zone 3, etc. Additionally, any number of zones can be used. For example, every word line can have a different thickness in one embodiment. In another embodiment, two zones can be used with all of the word lines having one of two thicknesses.

By way of example, FIG. 10 illustrates a first word line layer (e.g., WL1) that is formed below a second word line layer (e.g., WL2). Word line WL1 has a thickness and therefore gate length that is smaller than the thickness and gate length of word line WL2. The first word line is formed at a first level above the substrate 201 and the second word line is formed at a second level above the substrate 201. The first level is a smaller distance from the surface of substrate 201 than the second level.

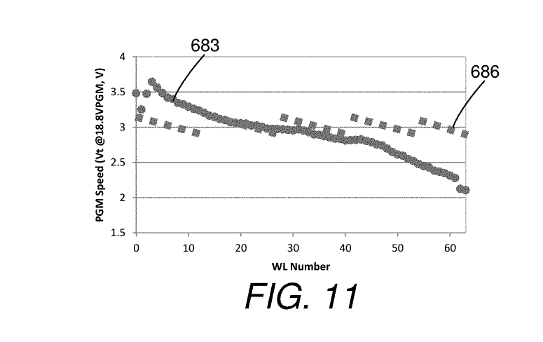

FIG. 11 is a graph showing the programming speed for a group of word lines coupled to a memory hole having a diameter that is smaller at the bottom and larger at the top. Line 683 illustrates that the programming speed gradually decreases from word line 0 to word line 63 when the word lines have the same thickness. Line 686 shows the results when the word lines have thicknesses that vary based on the memory hole diameter. Line 686 continues with the example of FIG. 10 where the word lines are divided into five zones. Each zone is formed with a thickness that is larger than that of the zones below it. Line 686 illustrates that the memory cells show a more consistent programming speed across the word lines. The zones can be seen in line 686 by the grouping of the memory cells. For example word lines 0-13 correspond to zone 1, word lines 14-26 correspond to zone 2, word lines 27-39 correspond to zone 3, word lines 40-52 correspond to zone 4, and word lines 53-63 correspond to zone 5. It can be seen that the word lines in each zone exhibit a similar programming behavior. Programming for the word lines in zone 1 is decreased from its programming speed shown by line 683 due to decreasing the word line gate length. Programming for the word lines in zone 2 is slightly decreased due to decreasing the word line gate length by a smaller amount. Programming for the word lines in zone 3 is about the same. Programming for the word lines in zones 4 and 5 is increased due to increasing the gate length of the word lines in these zones.

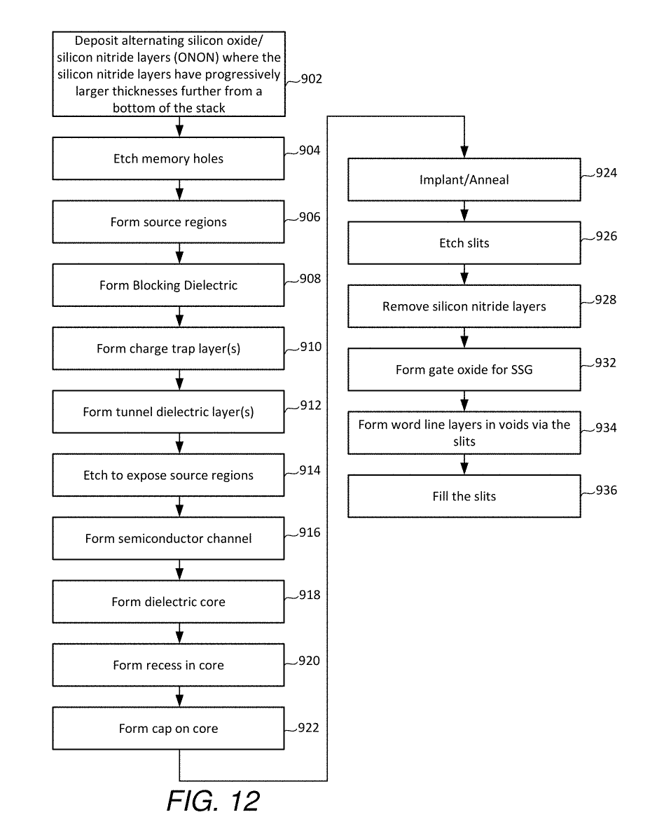

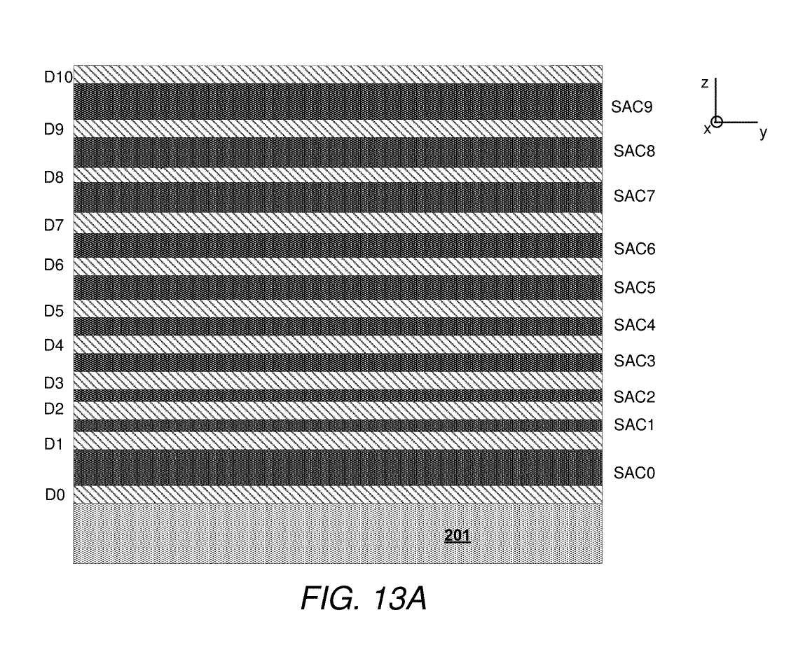

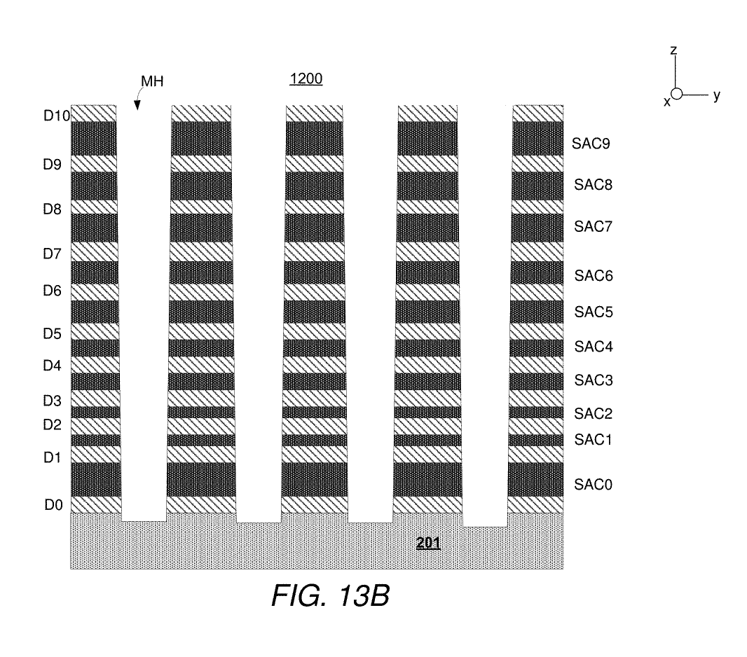

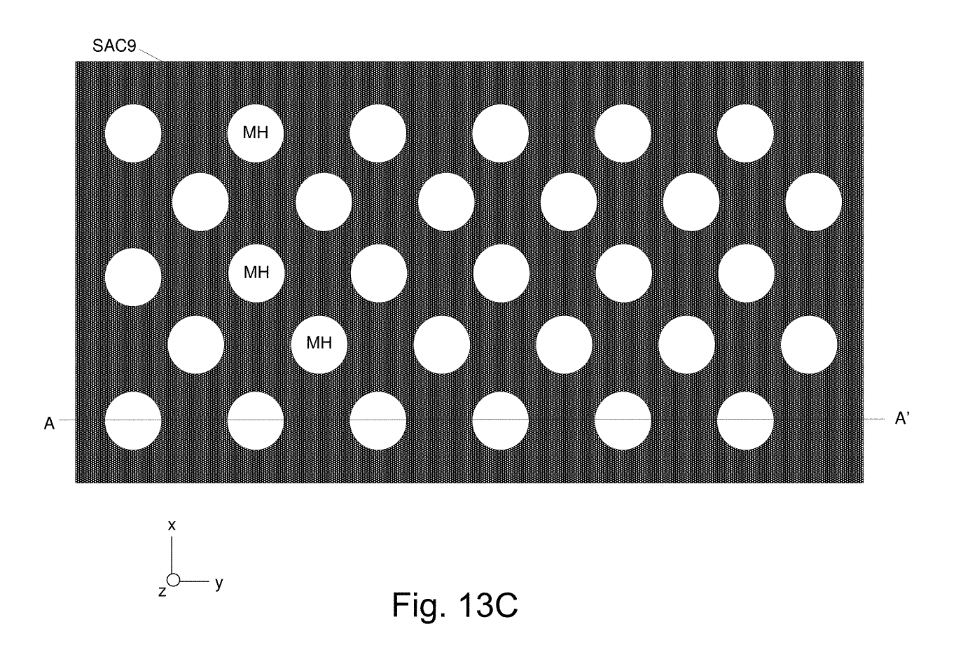

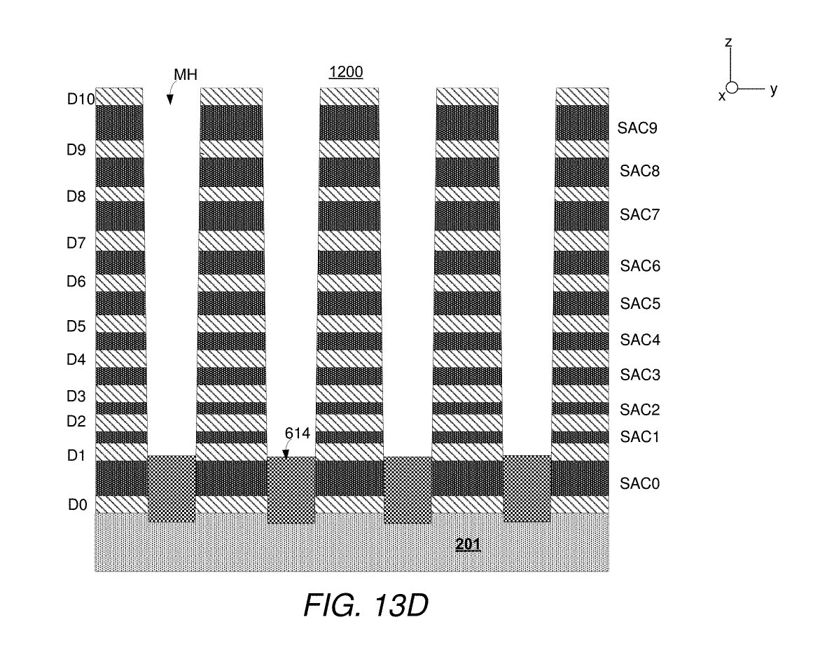

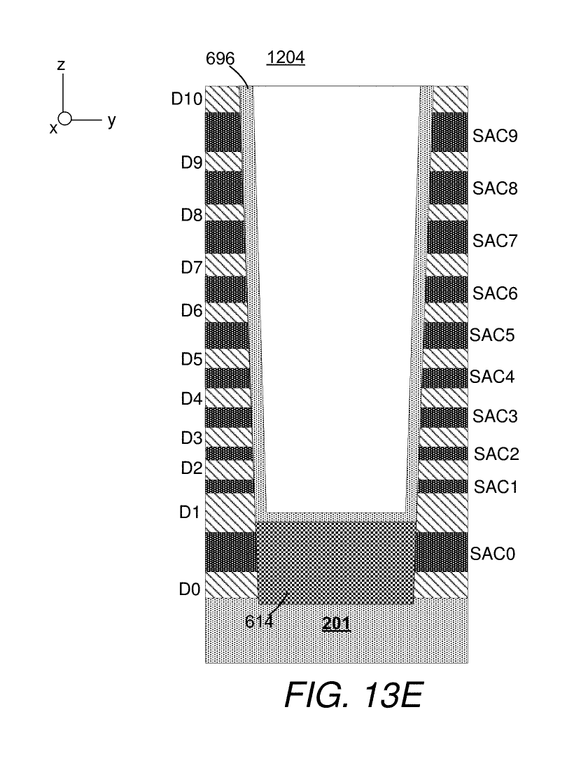

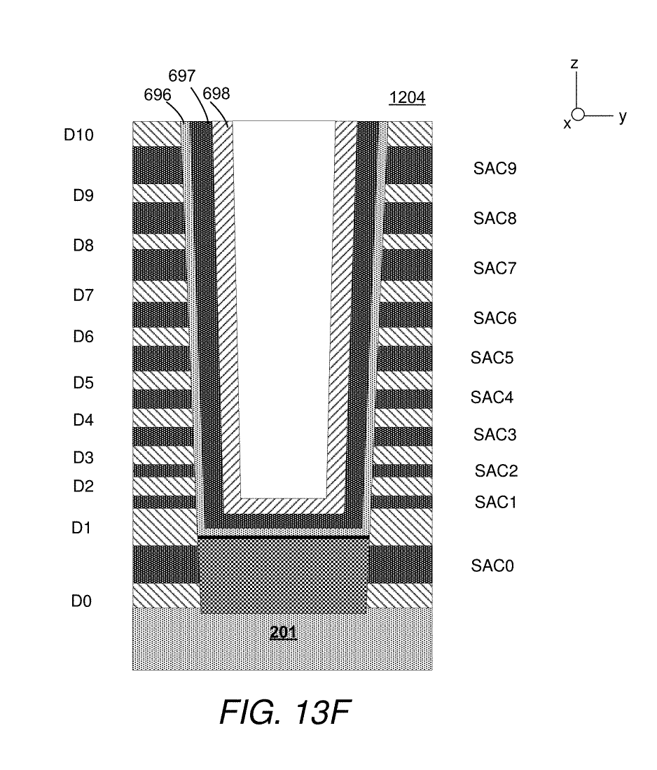

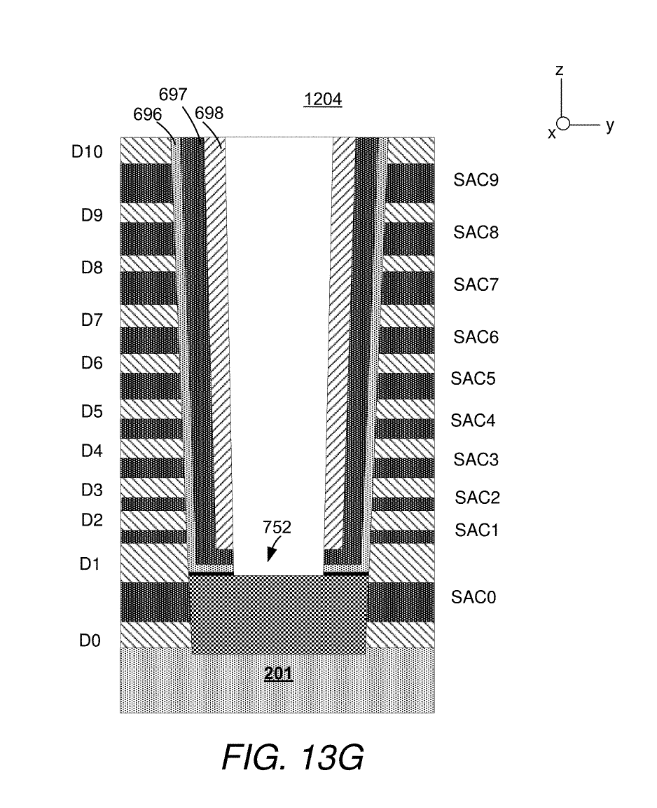

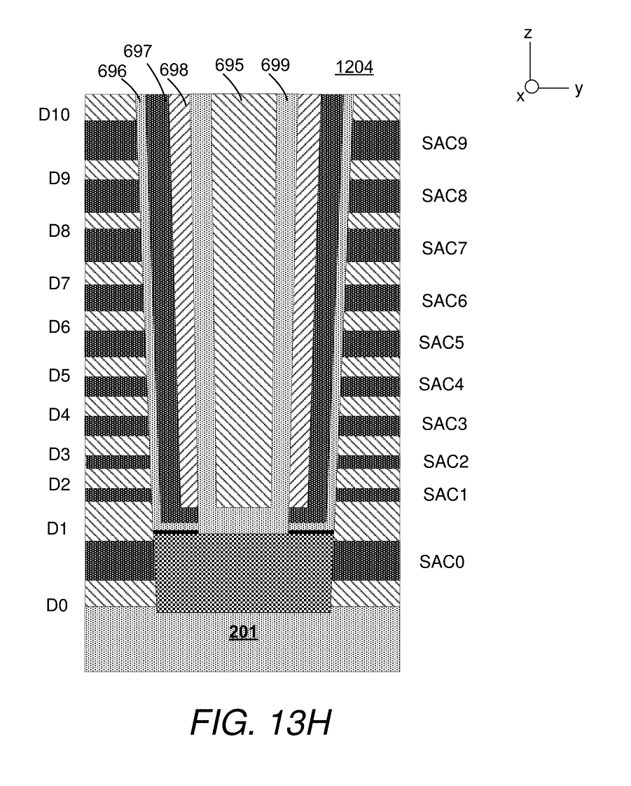

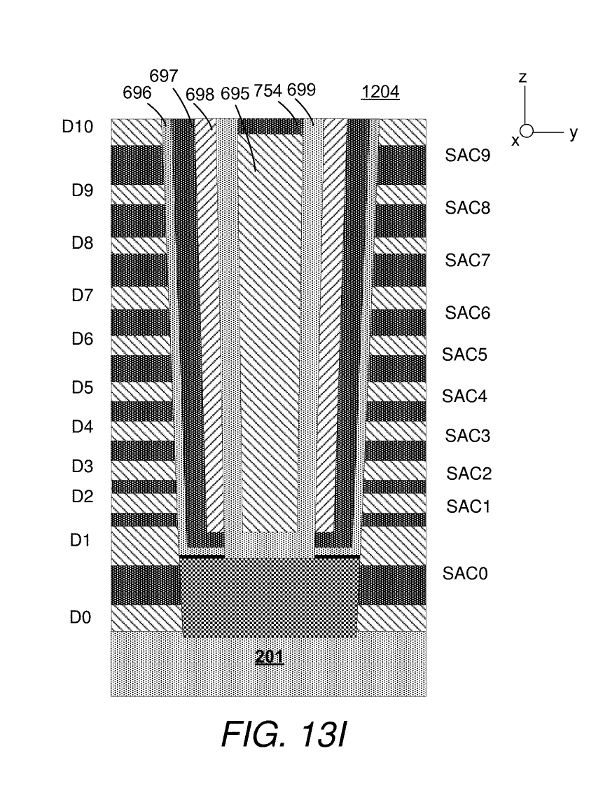

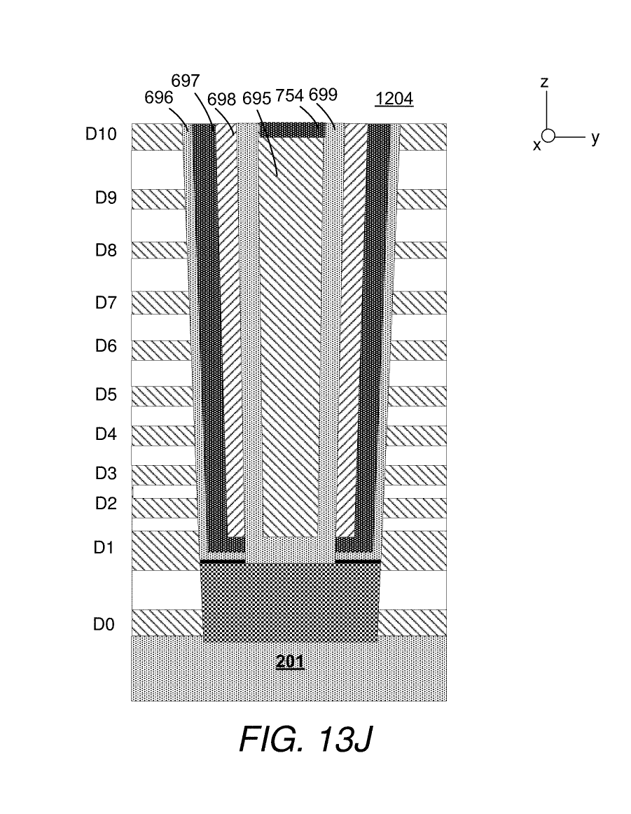

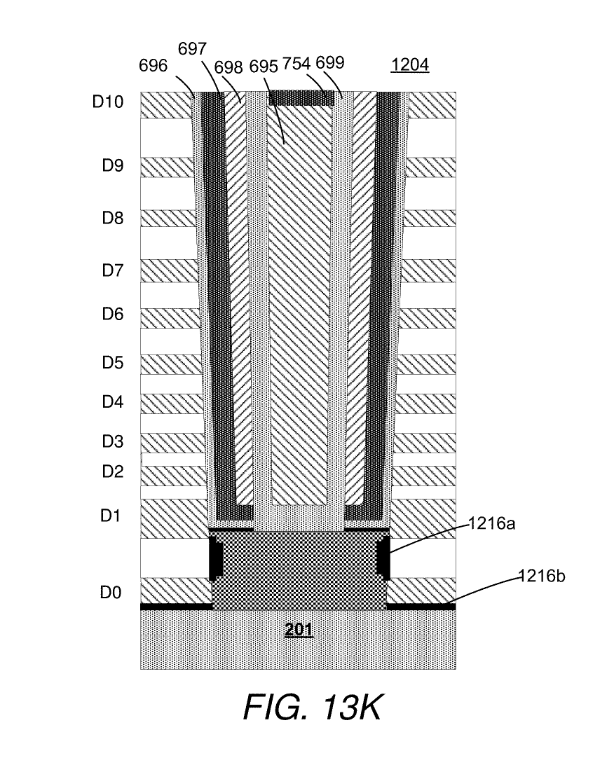

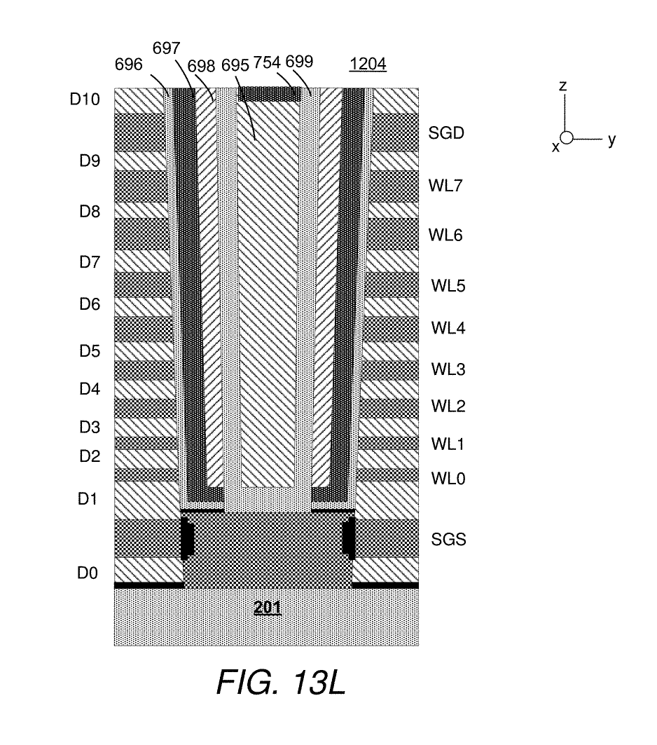

FIG. 12 is a flowchart of one embodiment of a process of fabricating a memory device having a variable word line thickness based on a corresponding memory hole diameter. The process may be used for fabricating a 3D memory array (such as 3D NAND). Devices such as, but not limited to, those depicted in FIGS. 2, 3A, 3B, 4A, 4B, and 4C can be fabricated. Straight NAND strings in a 3D memory array can be fabricated in one embodiment. U-shaped NAND strings in a 3D memory array can be fabricated in one embodiment. Note that steps may be performed in a different order than presented in the flowchart. FIGS. 13A-13L depict the results of various process steps outlined in FIG. 12. Various modifications can be made. Moreover, other steps which are known from the art of semiconductor fabrication but are not explicitly depicted here may also be performed. FIG. 12 represents a “word line last” technique in which the word lines are formed after forming the NAND strings. For example, after forming the NAND strings, sacrificial silicon nitride may be replaced, at least in part, with metal. Other techniques can also be used.

Prior to step 902 of FIG. 12, below-stack circuitry and metal layers may be formed in the substrate. Various circuits may be formed in/on substrate 201. For example, a metal layer M0 can be used, e.g., for power line and global control signals, and a metal layer M1 can be used, e.g., for bit line and bus signals. In some cases, to make signal routing easier and to save area, a third metal (M2) can also be used, e.g., a total of three (or more) metal layers under the array. The metal layers can be fabricated from a patterned metal film. For example, aluminum can be used for the top metal layer, while the other layers are tungsten. Potentially, copper can be used instead of aluminum for upper layer, using a corresponding integration scheme. For silicidation, Ni, Ti, Co or W can be used, for instance.

At step 902, alternating silicon oxide (SiO₂)/silicon nitride (SiN) layers are deposited above the substrate 201. The silicon nitride is a sacrificial layer, which will be replaced by metal to form word lines (as well as a source select line (SGS), and a drain select line (SGD or SG). The silicon oxide will be used for the insulating/dielectric layers between the metal word (and select) lines. Other insulators can be used instead of silicon oxide. Other sacrificial materials could be used instead of silicon nitride.

The sacrificial layers for the word lines are formed with a thickness that varies with a distance of the sacrificial layer from the substrate surface. The sacrificial layers, which will later be removed to form word lines in their place, are formed with a smallest thickness for the lowest word line closest to the substrate surface and with a largest thickness for the highest word line furthest from the substrate surface. Thus, the sacrificial layers are formed with a progressively larger thickness from a bottom of the stack. In one embodiment, a thicker layer may be formed by using a longer deposition time when forming the corresponding word line layer. Other techniques may be used to adjust the thickness of the individual sacrificial layers.

FIG. 13A depicts the results of step 902 in one embodiment. Sacrificial nitride layers SAC0-SAC9 have been formed alternatingly with dielectric layers D0-D10 over a semiconductor substrate to form a stack 1200. Sacrificial layer SAC0 will eventually become the SGS layer, and sacrificial layer SAC9 will eventually become the SGD layer. Sacrificial layers SAC1-SAC8 will eventually become word lines WL0-WL7. In this particular example, sacrificial layers SAC1 and SAC2 have a first thickness, sacrificial layers SAC2 and SAC4 have a second thickness that is larger than the first thickness, sacrificial layers SAC5 and SAC6 have a third thickness that is larger than the second thickness, and SAC7 and SAC8 have a fourth thickness that is larger than the third thickness. Sacrificial layers SAC0 and SAC9 can be formed with various thicknesses. In this example, SAC0 and SAC9 have a thickness than is larger than the fourth thickness of SAC7 and SAC8. Dielectric layers D0-D10 have the same thickness in FIG. 13A but different thicknesses for the dielectric layers could also be used.

At step 904, memory holes (MH) are etched in the stack of alternating layers of silicon nitride and silicon oxide. Reactive ion etching can be used to etch the memory holes. In the memory array area, the memory holes are placed densely. For example, the memory holes can have a diameter of 70-110 nanometers (nm) (70-110×10⁻⁹ meters). This is an example range; other ranges could be used. Etching the memory holes creates a tapered profile to the memory holes such that the diameter is progressively smaller toward the bottom of the memory hole.

FIG. 13B shows the results of step 904 in one embodiment. Memory holes MH have been etched into the stack and extend vertically through the alternating sacrificial SAC0-SAC9 and insulating layers D0-D10. The memory holes extend fully through the stack to the semiconductor substrate 201, which is formed from silicon in one embodiment. Etching the memory holes may etch partway into the semiconductor substrate 201. An x-y-z coordinate system is depicted, showing the direction of formation. The memory holes have a major axis that is parallel to the z-axis.

FIG. 13C is a top view after step 904, showing one possible pattern for the memory holes (MH). An x-y-z coordinate system is depicted, showing that direction of formation. Note that line A-A′ indicates that FIG. 13A is a cross section along line A-A′ of FIG. 13C. Also note that the memory holes have a circular cross section in the horizontal direction (e.g., x-y plane), in this example. The memory holes are not required to be circular in cross section. Note that the memory holes could be of different diameter in the different layers. For example, the memory holes may have a smaller diameter at the lower layers as described. Moreover, the pattern of FIG. 13C is not the only possible pattern. For example, the memory holes do not need to be staggered as depicted.

At step 906, source regions are formed in the memory holes. Silicon is formed at the bottom of the memory holes for the source side select transistor bodies. In one embodiment, the silicon is mono-crystalline silicon. Step 906 includes epitaxial silicon growth at the bottom of the memory holes, in one embodiment. In one embodiment, precursors such as dicholorosilane (DCS) and HCl are used. Step 906 includes two sub-steps, in one embodiment. In a first sub-step, a bake in hydrogen is performed. This bake may be at about 750 to 950 degrees Celsius and may be for between about ten seconds to 150 seconds. As one example, the hydrogen gas flow rate is about 10 to 50 sccm. As one example, the pressure may be about 10 to 30 mTorr. Also, a nitrogen gas flow may be used to mitigate unintentional nucleation sites on nitride corners. The nitrogen gas flow may be about 10 to 50 sccm. This optional nitrogen gas flow step passivates dangling silicon bonds prior to epitaxial silicon growth. The vertical sidewalls of the memory holes may have unintentional nucleation sites. The unintentional nucleation sites may be dangling silicon bonds. Passivating the dangling silicon bonds helps to prevent unintentional growth of silicon on the vertical sidewalls of the memory holes. Such growth could potentially block the memory hole during the formation of materials in the memory holes. The entire growth process may be carried out in a Chemical Vapor Deposition (CVD) technique (single wafer process or batch).

FIG. 13D depicts the results of step 906 in one example, showing mono-crystalline silicon region 614 in the bottom of the memory holes (MH). Note that silicon region 614 will serve as the body of the source side select transistor.

At step 908, the blocking dielectric is formed. In one embodiment, step 908 includes forming an oxide blocking dielectric but other materials may be used. The blocking dielectric may include one or more blocking dielectric layers. The blocking dielectric may include an Al₂O₃ and an SiO₂ layer in one example. Together, the two layers make up the blocking dielectric layer 696. The blocking dielectric can be formed by atomic layer deposition, chemical vapor deposition, or other processes

FIG. 13E depicts the results of step 908 in one example, showing the formation of blocking dielectric 696. FIG. 13E shows a portion 1204 of stack 1200 containing just one of the memory holes from FIGS. 13A, 13B, 13C, and 13D. Blocking dielectric 696 is formed on the exposed sidewalls of the silicon nitride sacrificial layers and the silicon oxide insulating layers in the memory holes. Blocking dielectric 696 is also formed on the exposed surface of the mono-crystalline silicon 614 at the bottom of the memory hole. The oxide provides a high wet etch selectivity for later removal of the sacrificial silicon nitride.

At step 910, one or more charge trapping layers (CTL) are formed in the memory holes. A single charge trapping layer is used in one embodiment, but multiple charge trapping layers may be used. These layers may be deposited as several conformal layers over vertical sidewalls of the memory holes, as well as over the silicon region 614. FIG. 13F depicts results after step 910.

In one example, three charge trapping layers can be used. A first charge trapping layer is deposited as a conformal layer over exposed vertical sidewalls of the memory holes, as well as over the oxide 696 on the bottom of the memory hole. A second charge trapping layer is deposited as a conformal layer over exposed vertical sidewalls of the first charge trapping layer, as well as over the first charge trapping layer at the bottom of the memory hole. A third charge trapping layer is deposited as a conformal layer over exposed vertical sidewalls of the second charge trapping layer, as well as over the second charge trapping layer at the bottom of the memory hole.

The first charge trapping layer, the second charge trapping layer, and the third charge trapping layer may be formed from materials including, but not limited to, those discussed in connection with FIG. 7A. By way of non-limiting example, the charge trapping layer may include one or more of Charge storage layer 708 may be, but is not limited to, HfO₂, ZrO₂, Y₂O₃, La₂O₃, ZrSiO₄, BaZrO₂, BaTiO₃, T₂O₅, Zr₂SO₃, Si₃N₄, ZrSO₄ The charge trapping layers could be deposited using ALD or CVD, for example. Table I lists a few combinations for the charge trapping layers.

TABLE I

| Third (Inner) | Second (Middle) | First (Outer) |
|---|---|---|
| Si₃N₄ | High-k | Si₃N₄ |
| Si₃N₄ | High-k | La₂O₃ |
| La₂O₃ | High-k | Si₃N₄ |
| La₂O₃ | High-k | La₂O₃ |
| LaAlO₃ | High-k | La₂O₃ |

In one embodiment, one or more of the charge trapping layers are implanted with metallic or other dopants (e.g., As, Ge, Zn). This may increase the ability of the charge trapping layer to store charge. The charge trapping layers could be amorphous, poly-crystalline, or mono-crystalline. Crystalizing a charge trapping layer may increase the k-value.

Example thicknesses of the charge trapping layers are 2 to 3 nm for the third charge trapping layer (closest to channel), 4 to 6 nm for the second charge trapping layer (middle), and 2 to 3 nm for the first charge trapping layer (furthest from the channel). As one specific example, 2 to 3 nm for silicon nitride in the first charge trapping layer, 4 to 6 nm for a high-k dielectric in the second charge trapping layer, and 2 to 3 nm for silicon nitride in the third charge trapping layer can be used. The thickness numbers above are provided for illustration only; the thicknesses of each of the layers may be smaller or bigger. Also, the combination of thicknesses can be different than these examples.

At step 912, one or more tunnel dielectric layers are formed in the memory holes. The tunnel dielectric 698 may be deposited as a conformal layer on the charge trapping region layer. Thus, the tunnel dielectric 698 may cover vertical sidewalls of the charge trapping layer 697, as well as the portion of the charge trapping region 697 that is on the silicon region 614.

Step 912 may include depositing multiple layers, such as SiO₂ and SiON, with the SiO₂ nearest the charge trapping region. The tunnel dielectric might also include SiO₂ and ISSG (in-situ steam generation) formed oxide, with the SiO₂ nearest the charge trapping region. The tunnel dielectric might include three layers: SiO₂, SiON, and ISSG formed oxide. However, any number of materials may be used including Si₃N₄ and SiN.

FIG. 13F depicts results after step 912 in one embodiment. Tunnel dielectric layer 698 is deposited as a conformal layer over exposed vertical sidewalls of the charge trapping layer 697, as well as over the charge trapping layer 697 on the bottom of the memory hole. Although not shown, a protective layer may be formed over the tunnel dielectric 698. For example, amorphous silicon oxide can be deposited as a conformal layer over exposed vertical sidewalls of tunnel dielectric layer 698, as well as over the tunnel dielectric layer 698 at the bottom of the memory hole.

At step 914, the bottom of the memory holes are etched to expose the silicon region 614. In one embodiment, this is a reactive ion etch (RIE). A post wet etch clean can be used as well to remove any protective layer that is applied. In one embodiment, a wet etch is used to remove the protective layer and polymer residues from the etch forming the memory holes.

FIG. 13G shows results of step 914 in one embodiment. Etching creates an opening 752 at the bottom of the memory hole, exposing the surface of the silicon 614 that will be the body of the source side select transistor.

At step 916, the semiconductor channels are deposited in the memory holes. In one embodiment, amorphous silicon is deposited. This may be deposited as a conformal layer over the exposed sidewalls of the tunnel dielectric in the memory holes, as well as over the exposed silicon 614 at the bottom of the memory hole. The semiconductor channel could be formed from a semiconductor other than silicon.

At step 918, a core of silicon oxide, for example, is formed in the memory holes. ALD is used in one embodiment. FIG. 13H shows the results of steps 916 and 918. The silicon channel 699 is shown as a conformal layer over sidewalls of tunnel layer 698, as well as over the top of the silicon 614 at the bottom of the memory hole. The SiO₂ core 695 is depicted is filling the remaining portion of the memory hole.

At step 920, a recess is formed in the SiO₂ core 695. This is a dry etch in one embodiment. At step 922, amorphous silicon is deposited in the recess in the SiO₂ core 695. The amorphous silicon may be deposited by CVD. At step 924, an impurity is implanted into the amorphous silicon. The doping may be in situ. The impurity could be arsenic, phosphorous, boron, or a combination thereof, but is not limited thereto. At step 924, an activation anneal is performed. This reduces the contact resistance. FIG. 13I depicts the results of steps 920-924 in one example, showing a silicon cap 754 at the top of the SiO₂ core 695.

At step 926, slits are etched in the alternating silicon oxide (SiO₂)/silicon nitride (SiN) layers. In another example, slits may be etched earlier in the process and filled with an insulator. In such a case, step 928 can include etching to remove the insulator instead of etching the alternating SiO₂ and SiN layers directly. FIGS. 4B and 4C show examples of slits 502 for straight NAND strings. FIG. 3B shows one example of slits 408 for U-shaped NAND strings. The pattern in which the slits are formed can vary widely. In one embodiment, the slits are a light trench formation process used to form source side contacts to the memory hole.

At step 928, an etch is performed via the slits to remove portions of the silicon nitride layers. The etch can involve introducing an etchant via the slits, which has a higher selectivity for the silicon nitride, removing the silicon nitride layers. The wet etch is not relatively highly selective of the silicon oxide so that the silicon oxide is not substantially removed. The etch may have a relatively higher selectivity (e.g., by a factor of 1000, or more generally, 100 or more) for the silicon nitride relative than for the silicon oxide. Also note that the etch should not remove the NAND strings. Note that the blocking dielectric 696 may serve as an etch stop.

FIG. 13J depicts the results of step 928 in one example. The wet etch should remove essentially the entire silicon nitride layers wherein the NAND strings are being formed (memory cell area), so that when the regions of the removed silicon nitride are replaced by metal, the metal will extend in substantially the entire layer in the memory cell area. Thus, word line layers at different levels should be isolated from one another and not shorted together. This applies regardless of the etch method, e.g., whether the etchant is introduced via the slits, memory holes, other holes or recesses, or combinations thereof. The NAND strings in the memory holes serve as anchors which support the silicon oxide layers when the silicon nitride is removed by etching through slits.

A variety of etching techniques may be used to etch the silicon nitride. Nitride can be etched in one embodiment, by heated or hot phosphoric acid (H₃PO₄). As an example, the boiling point of phosphoric acid varies with the concentration of the acid. For example, for a range of acid concentration between 79.5%-94.5% the boiling point may vary from 140° C.-200° C. The etch rate of silicon nitride varies with the temperature and the concentration of the acid. Since the bath is operated at high temperature, water readily evaporates from the solution and the concentration of phosphoric acid changes. Therefore, this may be considered to be a type of “wet” etch. However, a wet etch is not necessarily needed for nitride, as other etching techniques may be applied. In other embodiments, the sacrificial material in the stack may be something other than silicon nitride. Therefore a different type of etch process and etchant may be used.

Note that rather than performing the etch through the slits to remove the sacrificial material, the sacrificial material could be removed by etching through holes, recesses, etc. In another embodiment, the sacrificial material is removed at an earlier stage of the process by etching through the memory holes to remove the sacrificial material. In such an embodiment, the slits can be filled with a material that serves as an anchor when etching through the memory holes.

At step 932, a gate oxide for the source side select gate (SSG) is formed. Step 932 may include water vapor generator (WVG) oxidation of exposed silicon 614 at the bottom of the memory holes. This step serves to form the gate oxide of the source side select transistors. The WVG oxidation selectively oxidizes silicon. Also, the surface of the substrate may also be oxidized.

FIG. 13K shows results after step 932 in one example. The gate oxide 1216a for the source side select transistor is shown on vertical sidewalls of silicon 614. Also, oxide 1216b is shown on the surface of the substrate 201. Note that the substrate 201 is a p-substrate, at least near the oxide 1216b, in one embodiment.

At step, 934 a conductive material (one or more layers) such as metal is formed in the recesses via the slits. In one embodiment, the metal is tungsten. This forms a metal/oxide stack. Metal is provided in the slits to fill the recesses left when the sacrificial material was removed. Chemical vapor deposition (CVD) or atomic layer deposition (ALD) could be used to deposit the metal. In one embodiment, first a tungsten nucleation layer is formed, then tungsten is deposited by CVD.

At step 936, the slits are re-filled. A tungsten recess may be performed to isolate the word lines. Also a cover TEOS may be deposited by CVD.

FIG. 13L shows the results of steps 934 and 936 in one example. The sacrificial layers SAC0-SAC7 have been replaced by metal layers SGS, WL0-WL7, and SGD, respectively. Although not shown, an aluminum oxide blocking layer can be formed, followed by a titanium nitride barrier layer in the holes where the sacrificial material was removed prior to forming the conductive material for the word lines.

Looking back at FIG. 7, the profile and shape of the memory holes (e.g., such as memory hole MH of FIG. 7) is such that they have a varying diameter which becomes progressively and gradually narrower from the top of the stack to the bottom of the stack. That is, the top of the memory hole (and the top of the memory column) is wider than the bottom of the memory hole (and the bottom of the memory column). In some cases the memory holes may bow somewhere in the middle. At the top portions of the stack (alternating word line layers WL0, WL1, . . . and dielectric layers D1, D2, . . . ) where the memory holes are wider, there is less word line material (also known as gate material) for two reasons.

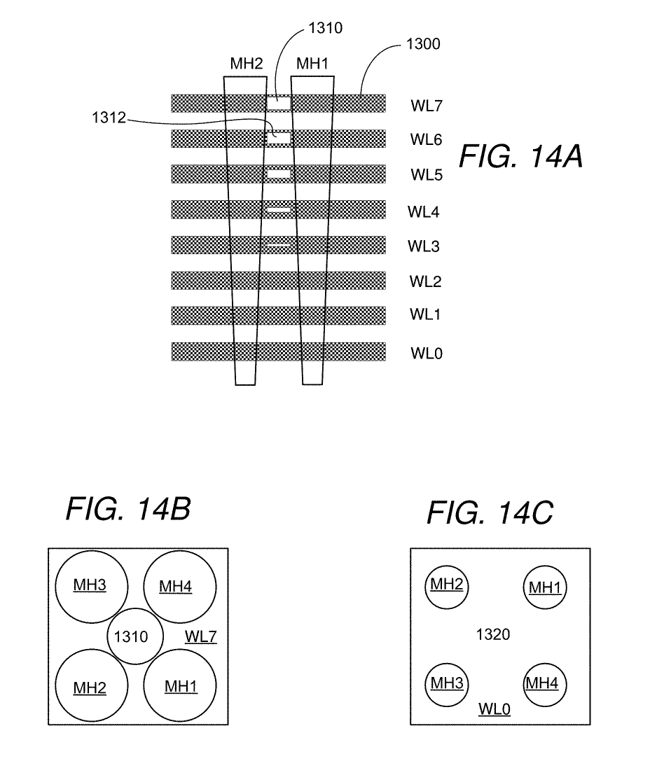

First, there is less space between memory holes for the word line material. This is concept is graphically depicted in FIGS. 14A-C. FIG. 14A which shows a side view of the stack 1300 and two memory holes MH1 and MH2. Stack 1300 includes word line layers WL0, WL1, WL2, WL3, WL4, WL5, WL6 and WL7 alternating with dielectric/insulator layers (not depicted in FIG. 14A). Although eight word line layers are depicted, various embodiments can include more or less than eight word line layers (e.g., 48 word line layers, 64 word line layers, 128 word line layers, etc.). FIG. 14B is a top view of memory holes MH1, MH2, MH3 and MH4, as well as stack 1300, although only WL7 of stack 1300 is visible in FIG. 14B. Note that memory holes MH3 and MH4 are not visible in FIG. 14A as they are behind memory holes MH1 and MH2. FIG. 14C is a bottom view of memory holes MH1, MH2, MH3 and MH4, as well as stack 1300, although only WL0 of stack 1300 is visible in FIG. 14B. As can be seen, the diameters of memory holes MH1, MH2, MH3 and MH4 are larger in FIG. 14B than in FIG. 14C, as FIG. 14A depicts the top where the memory holes are wider. The area between memory holes MH1, MH2, MH3 and MH4 in FIG. 14B (represented by circle 1310) is smaller than the area 1320 between memory holes MH1, MH2, MH3 and MH4 in FIG. 14C; therefore, there is less word line material.

Second, because of the larger diameter or width of the memory holes at the top of the stack, the area between memory holes can get pinched off during deposition, making it impossible for the precursor gases to reach the area at the center between neighboring memory holes, thereby creating WL gap-fill voids between memory holes. For example, FIG. 14A labels the top two WL gap-fill voids 1310 and 1312. The WL gap-fill voids get smaller as the diameter/width of the memory holes gets smaller. These WL gap-fill voids (e.g., 1310 and 1312) decrease the available volume of word line material (e.g., Tungsten W) for the upper word lines. FIG. 14C shows that the bottom word lines do not have WL gap-fill voids.

Having less word line material results in a word line having a higher resistance than word lines with more word line material. Therefore, a word line at the top of the stack may have a higher resistance than a word line at the bottom of the stack. Having word lines with higher resistance will have a negative impact of performance during read operations because the settling time for word line voltages will be longer, which will slow down the read process. Therefore, it is proposed to implement the memory structure with word lines at the top of the stack having thicker word line layers than other word line layers so that the word lines at the top of the stack have a similar resistance as word lines at the bottom of the stack.

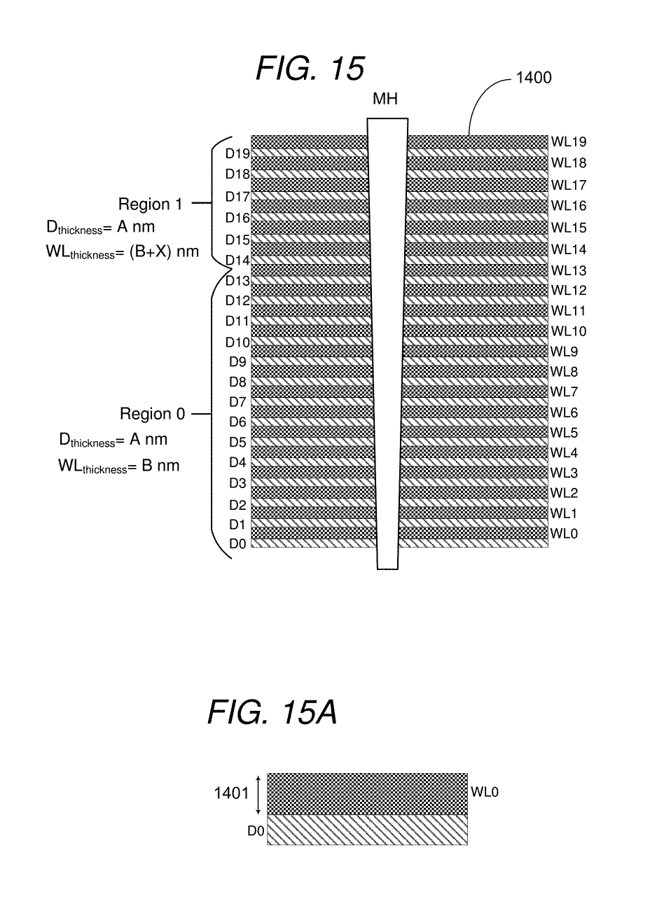

FIG. 15 is a cross-sectional view of a portion of a 3D stacked memory array having word lines with a gate length that varies based on vertical distance from a substrate surface such that word lines layers at the top of the stack are thicker than word line layers at the bottom of the stack. FIG. 15 shows a side view of stack 1400 and memory hole MH (which can include a column of materials that implements a NAND string). Memory hole MH (including the column of materials that implements a NAND string) has a diameter that decreases from an upper region of the stack to a lower region of the stack. Stack 1400 includes a plurality of word line layers WL0-WL19 (e.g., Tungsten) arranged alternatingly with the plurality of dielectric/insulating layers D0-D19. Although twenty word line layers are depicted, various embodiments can include more or less than twenty word line layers. Note that the term “thickness” used herein refers to the vertical height of the word line layers. For example, FIG. 15A is a close-up of a portion of word line layer WL0 and dielectric layer D0 of FIG. 15, with arrow 1401 graphically depicting thickness (also referred to as gate length).

Stack 1400 of FIG. 15 is divided into two regions: Region 0 and Region 1. Region 0 includes the bottom word lines of stack 1400. Region 1 includes the top word lines of stack 1400. The thickness of the word line layers of Region 1 is greater than the thickness of the word line layers of Region 0. In one embodiment, all of the word line layers of Region 0 have the same thickness and all of the word line layers of Region 1 have the same thickness. In other embodiments, the word line layers can vary within a region as long as the word line layers of Region 0 are thinner than the word line layers of Region 1.

In one embodiment, the thickness of the dielectric/insulator layers of Region 0 are all A nm and the thickness of the word line layers of Region 0 are all B nm. Example dimensions are A=27 nm and B=31 nm; however, other values can also be used. In one embodiment, the thickness of the dielectric/insulator layers of Region 1 are all A nm and the thickness of the word line layers of Region 1 are all (B+X) nm. Example values for X range from 1 nm-8 nm; however, other values can also be used. Therefore, in one example, the thickness of dielectric/insulator layers of stack 1400 are 27 nm, the thickness of word line layers of Region 0 are 31 nm and the thickness of word line layers of Region 1 are 32 nm.

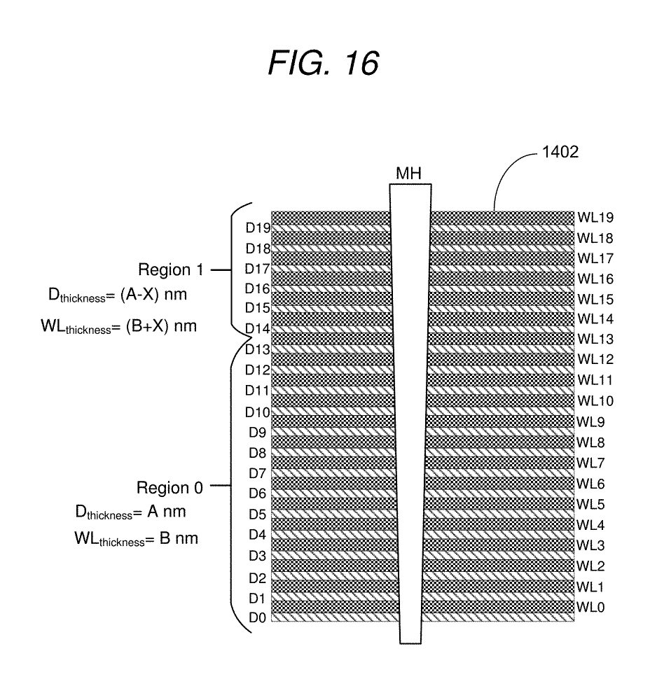

FIG. 16 is a cross-sectional view of a portion of another embodiment of a 3D stacked memory array having word lines with a gate length that varies based on vertical distance from a substrate surface such that word lines layers at the top of the stack are thicker than word line layers at the bottom of the stack. FIG. 16 shows a side view of stack 1402 and memory hole MH (which can include a column or materials that implements a NAND string). Stack 1402 is positioned over a substrate (not depicted in FIG. 16). Memory hole MH (including the column of materials that implements a NAND string) has a diameter that decreases from an upper region of the stack to a lower region of the stack. Stack 1402 includes a plurality of word line layers WL0-WL19 (e.g., Tungsten) arranged alternatingly with the plurality of dielectric/insulating layers D0-D19. Although twenty word line layers are depicted, various embodiments can include more or less than twenty word line layers.

Stack 1402 of FIG. 16 is divided into two regions: Region 0 and Region 1. Region 0 includes the bottom word lines of stack 1402 (e.g., WL0-WL13). Region 1 includes the top word lines of stack 1402 (e.g., WL14-WL19). Thus, although WL13 is an adjacent word line layer to WL14, they are in different groups and, as described below, will have different thicknesses. The thickness of the word line layers of Region 1 is greater than the thickness of the word line layers of Region 0. In one embodiment, all of the word line layers of Region 0 have the same thickness and all of the word line layers of Region 1 have the same thickness. In other embodiments, the word line layers can vary within a region as long as the word line layers of Region 0 are thinner than the word line layers of Region 1.

In the embodiment of FIG. 16, the thickness of the word line layers of Region 1 are increased in order to reduce gate resistance and the thickness of the dielectric/insulator layers of Region 1 are reduced respectively to keep the total thickness of each word line layer/dielectric layer pair the same. That is, the conductor (word line) layers and dielectric/insulator layers of stack 1402 are arranged as groups of adjacent conductor (word line) layers and dielectric/insulator layers. Examples of groups of adjacent conductor (word line) layers and dielectric/insulator layers are WL0/D0, WL1/D1, WL2/D2, etc. Each of groups of adjacent conductor (word line) layers and dielectric/insulator layers has a conductor thickness, an insulator thickness and a total thickness that is a sum of its respective conductor thickness and insulator thickness. In the embodiment of FIG. 16, the total thickness for the groups of adjacent conductor layers and insulator layers is constant but conductor thickness and insulator thickness may vary among at least a subset of the groups.

In one embodiment, the thickness of the dielectric layers of Region 0 are all A nm and the thickness of the word line layers of Region 0 are all B nm. Example dimensions are A=27 nm and B=31 nm; however, other values can also be used. In one embodiment, the thickness of the dielectric/insulator layers of Region 1 are all (A−X) nm and the thickness of the word line layers of Region 1 are all (B+X) nm. Example values for X range from 1 nm-8 nm; however, other values can also be used. Therefore, in one example where X=1, the thickness of the dielectric/insulator layers of Region 0 are all 27 nm, the thickness of the word line layers of Region 0 are all 31 nm, the thickness of the dielectric/insulator layers of Region 1 are all 26 nm, the thickness of the word line layers of Region 1 are all 32 nm, and the total thickness for the groups of adjacent conductor layers and insulator layers is 58 nm.

Looking at two word lines, WL4 and WL17, for example purposes, WL4 is below WL17, WL4 has a first word line thickness (31 nm), WL17 has a second word line thickness (32 nm), and the first word line thickness is smaller than the second word line thickness. Additionally, dielectric/insulator layer D4 is below dielectric/insulator D17, dielectric/insulator layer D4 has a first insulator thickness (27 nm), dielectric/insulator layer D17 has a second insulator thickness (26 nm), and the first insulator thickness is larger than the second insulator thickness. Note that WL4 is separated from WL17 by other word lines, WL4 is adjacent D4, and WL17 is adjacent D17.

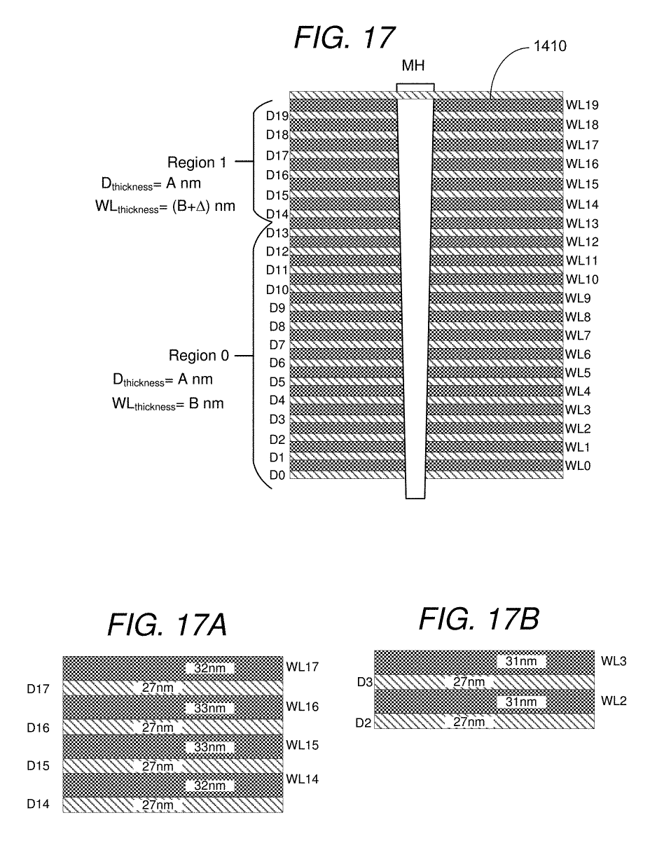

FIG. 17 is a cross-sectional view of a portion of another embodiment of a 3D stacked memory array having word lines with a gate length that varies based on vertical distance from a substrate surface such that word lines layers at the top of the stack are thicker than word line layers at the bottom of the stack. FIG. 17 shows a side view of stack 1410 and memory hole MH (which can include a column or materials that implements a NAND string). Stack 1410 includes word line layers WL0-WL19 alternating with dielectric/insulating layers D0-D19. Although twenty word line layers are depicted, various embodiments can include more or less than twenty word line layers. Stack 1410 of FIG. 17 is divided into two regions: Region 0 and Region 1. Region 0 includes the bottom word lines of stack 1410. Region 1 includes the top word lines of stack 1410. The thickness of the word line layers of Region 1 is greater than the thickness of the word line layers of Region 0.

In the embodiment of FIG. 17, the thickness of the word line layers within Region 1 may vary by as much as 0.5 nm to 3 nm (or within another range). Each word line layer of Region 1 will be made thicker than the word lines of region 0 by a variable Δ, where the Δ can be different for different word line layers of Region 1. In one example implementation, the stack 1410 can be simulated using software to predict word line layer resistances based on past manufacturing and testing. The higher the deviation in predicted resistance, the higher the Δ will be for the associated word line layer thickness to adjust the resistance.

In one embodiment, the thickness of the dielectric/insulator layers of Region 0 are all A nm and the thickness of the word line layers of Region 0 are all B nm. Example dimensions are A=27 nm and B=31 nm; however, other values can also be used. In one embodiment, the thickness of the dielectric/insulator layers of Region 1 are all A nm and the thickness of the word line layers of Region 1 are all (B+Δ) nm, where Δ varies among word line layers of Region 1 as discussed above. Example values for Δ range from 1 nm-8 nm; however, other values can also be used.

FIG. 17A depicts example thicknesses for a subset of the layers of Region 1. For example, FIG. 17A depicts dielectric/insulator layers D14, D15, D16 and D17 as well as word line layers WL14, WL15, WL16 and WL17. The thickness of dielectric/insulator layers D14, D15, D16 and D17 is depicted as 27 nm. The thickness of word line layer WL14 is 32 nm, the thickness of word line layer WL15 is 33 nm, the thickness of word line layer WL16 is 33 nm, and the thickness of word line layer WL17 is 32 nm.

FIG. 17B depicts example thicknesses for a subset of the layers of Region 1. For example, FIG. 17B depicts dielectric/insulator layers D2 and D3 as well as word line layers WL2 and WL3. The thickness of dielectric/insulator layers D2 and D3 is depicted as 27 nm. The thickness of word line layers WL2 and WL3 is 31 nm.

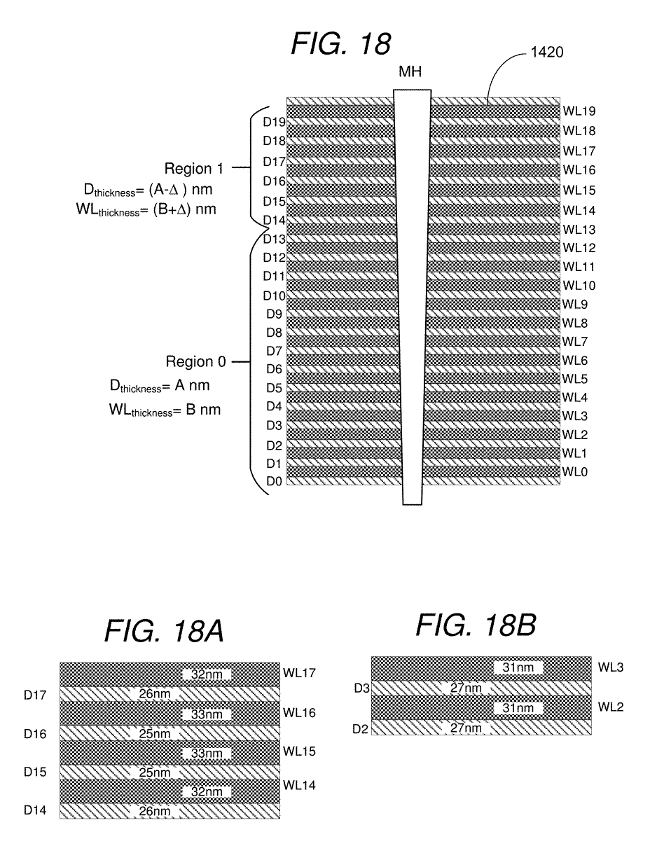

FIG. 18 is a cross-sectional view of a portion of another embodiment of a 3D stacked memory array having word lines with a gate length that varies based on vertical distance from a substrate surface such that word lines layers at the top of the stack are thicker than word line layers at the bottom of the stack. FIG. 18 shows a side view of stack 1420 and memory hole MH (which can include a column or materials that implements a NAND string). Stack 1420 includes word line layers WL0-WL19 alternating with dielectric/insulating layers D0-D19. Although twenty word line layers are depicted, various embodiments can include more or less than twenty word line layers. Stack 1410 of FIG. 17 is divided into two regions: Region 0 and Region 1. Region 0 includes the bottom word lines of stack 1420. Region 1 includes the top word lines of stack 1420. The thickness of the word line layers of Region 1 is greater than the thickness of the word line layers of Region 0.

In the embodiment of FIG. 18, the thickness of the word line layers within Region 1 may vary by as much as 0.5 nm to 3 nm (or within another range). Each word line layer of Region 1 will be made thicker than the word lines of region 0 by a variable Δ, where the Δ can be different for different word line layers of Region 1. In one example implementation, the stack 1410 can be simulated using software to predict word line layer resistances based on past manufacturing and testing. The higher the deviation in predicted resistance, the higher the Δ will be for the associated word line layer thickness to adjust the resistance.

In the embodiment of FIG. 18, the thickness of the word line layers of Region 1 are increased in order to reduce gate resistance and the thickness of the dielectric/insulator layers of Region 1 are reduced respectively to keep the total thickness of each word line layer/dielectric/insulator layer pair the same (see discussion of FIG. 16).

In one embodiment, the thickness of the dielectric/insulator layers of Region 0 are all A nm and the thickness of the word line layers of Region 0 are all B nm. Example dimensions are A=27 nm and B=31 nm; however, other values can also be used. In one embodiment, the thickness of the dielectric/insulator layers of Region 1 are all (A−Δ) nm and the thickness of the word line layers of Region 1 are all (B+Δ) nm, where Δ varies among word line layers of Region 1 as discussed above. Example values for Δ range from 1 nm-8 nm; however, other values can also be used.

FIG. 18A depicts example thicknesses for a subset of the layers of Region 1. For example, FIG. 18A depicts dielectric/insulator layers D14, D15, D16 and D17 as well as word line layers WL14, WL15, WL16 and WL17. The thickness of dielectric/insulator layers D14 and D17 is depicted as 26 nm. The thickness of dielectric/insulator layers D15 and D16 is depicted as 25 nm. The thickness of word line layer WL14 is 32 nm, the thickness of word line layer WL15 is 33 nm, the thickness of word line layer WL16 is 33 nm, and the thickness of word line layer WL17 is 32 nm.

FIG. 18B depicts example thicknesses for a subset of the layers of Region 1. For example, FIG. 18B depicts dielectric/insulator layers D2 and D3 as well as word line layers WL2 and WL3. The thickness of dielectric/insulator layers D2 and D3 is depicted as 27 nm. The thickness of word line layers WL2 and WL3 is 31 nm. Thus, for the embodiment of FIGS. 18, 18A and 18B, the total thickness of each word line layer/dielectric/insulator layer pair is 58 nm.

FIGS. 15-18 show embodiments with two regions (e.g., Region 0 and Region 1). However, other embodiments can have more than two regions.

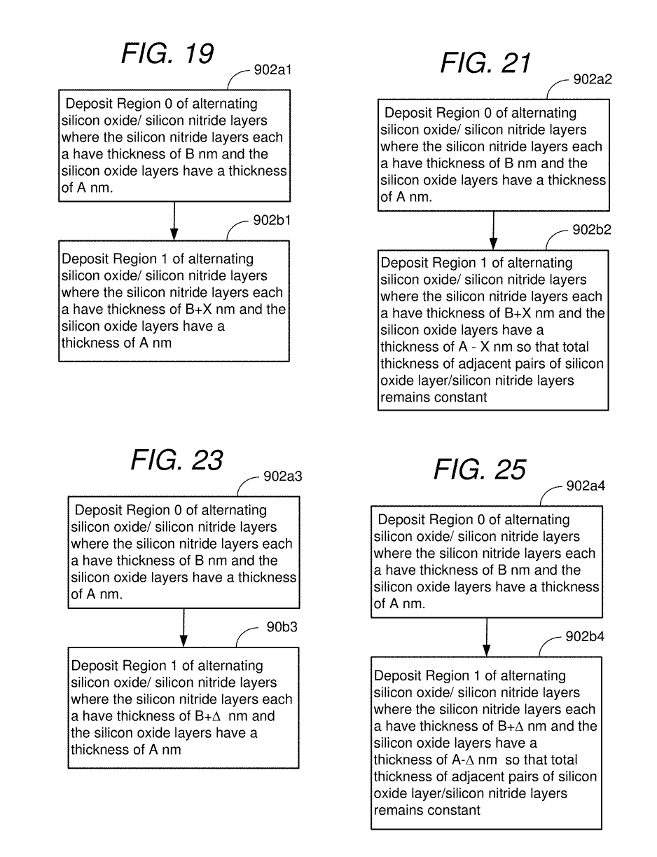

Looking back at FIG. 12, a flowchart is depicted that describes one embodiment of a process of fabricating a memory device having a variable word line thickness. This process of FIG. 12 can also be used to fabricate the memory device with a stack according to any of FIGS. 15-18, if step 902 is modified. FIGS. 19, 21, 23, and 25 are flow charts describing example implementations of processes for depositing alternating silicon oxide/silicon nitride layers. That is, the processes of FIGS. 19, 21, 23, and 25 are example implementations of step 902 of FIG. 12 for the embodiments of FIGS. 15-18.

The process of FIG. 19 is an example implementation of step 902 of FIG. 12 for the embodiment of FIG. 15. Step 902a1 includes depositing Region 0 of alternating silicon oxide/silicon nitride layers where the silicon nitride layers each a have thickness of B nm and the silicon oxide layers have a thickness of A nm. Step 902b1 includes depositing Region 1 of alternating silicon oxide/silicon nitride layers where the silicon nitride layers each a have thickness of B+X nm and the silicon oxide layers have a thickness of A nm. The silicon nitride is a sacrificial layer, which will be replaced by metal to form word lines (as well as a source select line (SGS), and a drain select line (SGD or SG). The silicon oxide will be used for the dielectric/insulator layers between the metal word (and select) lines. Other insulators can be used instead of silicon oxide. Other sacrificial materials could be used instead of silicon nitride.

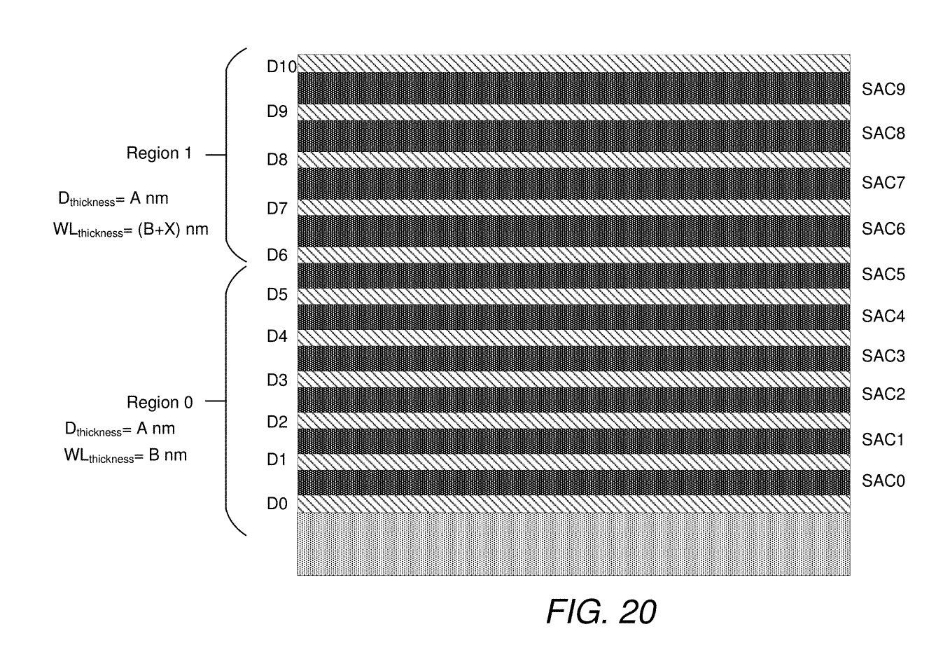

FIG. 20 depicts the results of one embodiment of steps 902a1 and 902b1. Thus, FIG. 20 replaces FIG. 13A in the discussion above. Sacrificial nitride layers SAC0-SAC9 have been formed alternatingly with dielectric/insulator layers D0-D10 over a semiconductor substrate to form a stack. The structure depicted in FIG. 20 is only a portion of the complete apparatus. In this particular example, sacrificial layers SAC1-SAC5 are in Region 0 and have a first thickness, and sacrificial layers SAC6-SAC9 are in Region 1 have a second thickness that is larger than the first thickness. Dielectric/insulator layers D0-D10 have the same thickness in FIG. 20 but different thicknesses for the dielectric/insulator layers could also be used.

The process of FIG. 21 is an example implementation of step 902 of FIG. 12 for the embodiment of FIG. 16. Step 902a2 includes depositing Region 0 of alternating silicon oxide/silicon nitride layers where the silicon nitride layers each a have thickness of B nm and the silicon oxide layers have a thickness of A nm. Step 902b2 includes depositing Region 1 of alternating silicon oxide/silicon nitride layers where the silicon nitride layers each a have thickness of B+X nm and the silicon oxide layers have a thickness of A−X nm so that total thickness of adjacent pairs of silicon oxide layer/silicon nitride layers remains constant

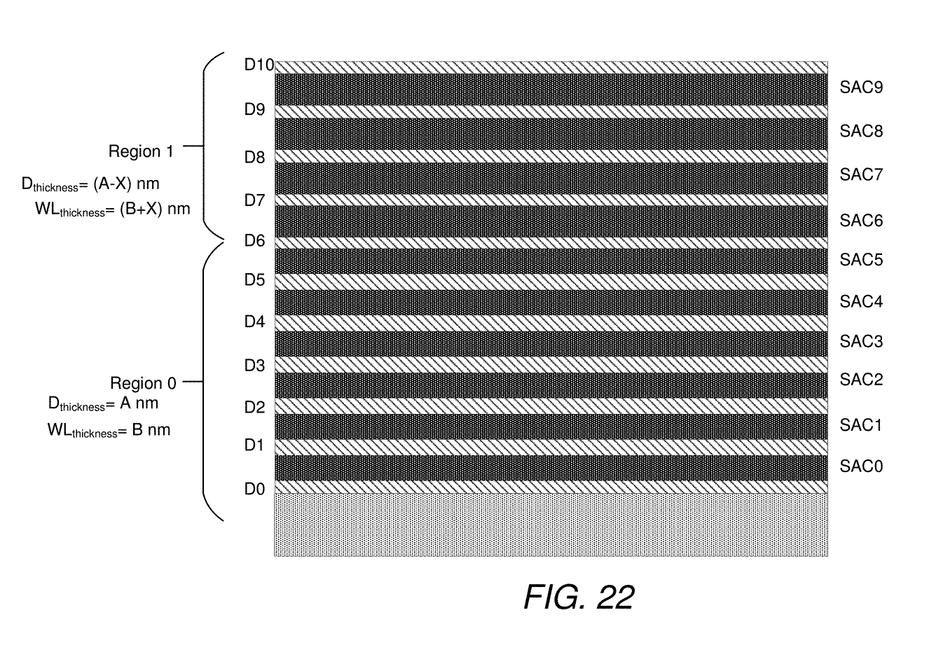

FIG. 22 depicts the results of one embodiment of steps 902a2 and 902b2. Thus, FIG. 22 replaces FIG. 13A in the discussion above. Sacrificial nitride layers SAC0-SAC9 have been formed alternatingly with dielectric/insulator layers D0-D10 over a semiconductor substrate to form a stack. The structure depicted in FIG. 22 is only a portion of the complete apparatus. In this particular example, sacrificial layers SAC1-SAC5 are in Region 0 and have a first thickness B nm, and sacrificial layers SAC6-SAC9 are in Region 1 have a second thickness B+X nm that is larger than the first thickness.

The process of FIG. 23 is an example implementation of step 902 of FIG. 12 for the embodiment of FIG. 17. Step 902a3 includes depositing Region 0 of alternating silicon oxide/silicon nitride layers where the silicon nitride layers each a have thickness of B nm and the silicon oxide layers have a thickness of A nm. Step 902b3 includes depositing Region 1 of alternating silicon oxide/silicon nitride layers where the silicon nitride layers each a have thickness of B+Δ nm and the silicon oxide layers have a thickness of A nm

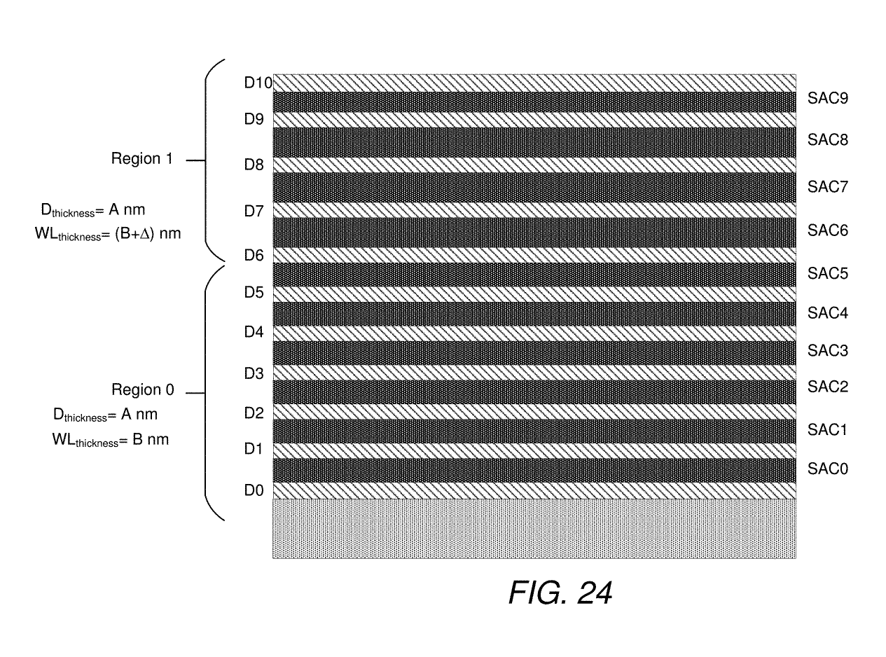

FIG. 24 depicts the results of one embodiment of steps 902a3 and 902b3. Thus, FIG. 24 replaces FIG. 13A in the discussion above. Sacrificial nitride layers SAC0-SAC9 have been formed alternatingly with dielectric/insulator layers D0-D10 over a semiconductor substrate to form a stack. The structure depicted in FIG. 24 is only a portion of the complete apparatus. In this particular example, sacrificial layers SAC1-SAC5 are in Region 0 and have a first thickness B nm, and sacrificial layers SAC6-SAC9 are in Region 1 have a thicknesses B+Δ nm (where A can vary by layer) that are larger than the first thickness.

The process of FIG. 25 is an example implementation of step 902 of FIG. 12 for the embodiment of FIG. 18. Step 902a4 includes deposit Region 0 of alternating silicon oxide/silicon nitride layers where the silicon nitride layers each a have thickness of B nm and the silicon oxide layers have a thickness of A nm. Step 902b4 includes depositing Region 1 of alternating silicon oxide/silicon nitride layers where the silicon nitride layers each a have thickness of B+Δ nm and the silicon oxide layers have a thickness of A−Δ nm so that total thickness of adjacent pairs of silicon oxide layer/silicon nitride layers remains constant.

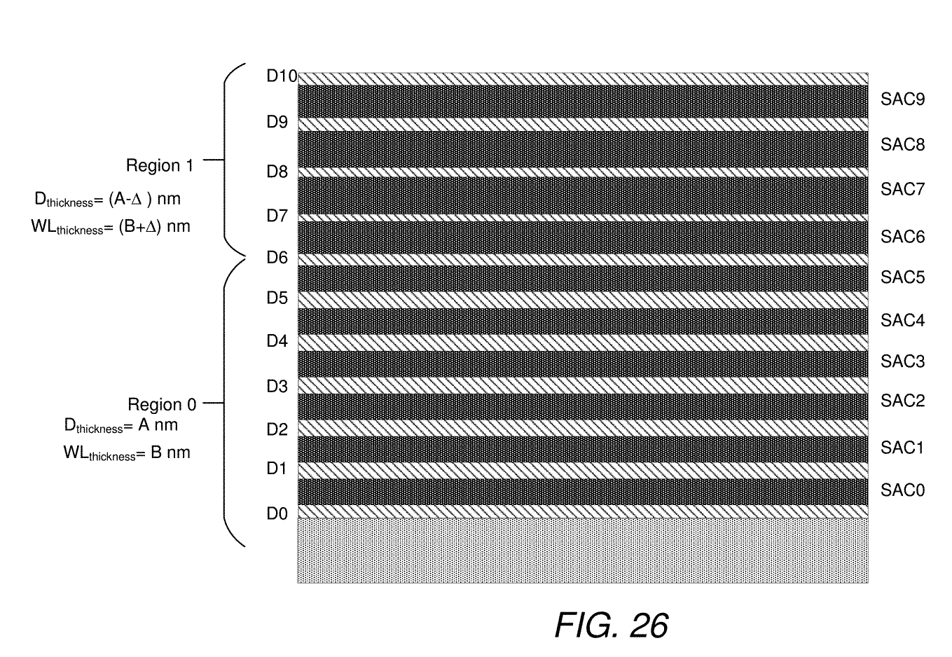

FIG. 26 depicts the results of one embodiment of steps 902a4 and 902b4. Thus, FIG. 26 replaces FIG. 13A in the discussion above. Sacrificial nitride layers SAC0-SAC9 have been formed alternatingly with dielectric/insulator layers D0-D10 over a semiconductor substrate to form a stack. The structure depicted in FIG. 26 is only a portion of the complete apparatus. In this particular example, sacrificial layers SAC1-SAC5 are in Region 0 and have a first thickness B nm, and sacrificial layers SAC6-SAC9 are in Region 1 have a thicknesses B+Δ nm (where A can vary by layer) that are larger than the first thickness.

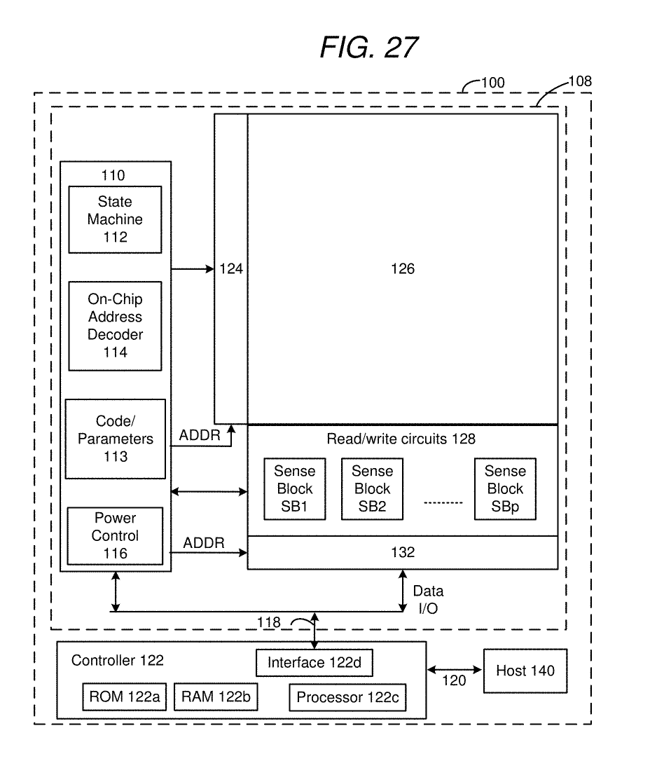

FIG. 27 is a functional block diagram of an example memory that includes a memory structure as described above with respect to FIGS. 1-26. The components depicted in FIG. 27 are electrical circuits. Memory device 100 includes one or more memory die 108. Each memory die 108 includes a three dimensional memory structure 126 of memory cells (such as, for example, a 3D array of memory cells), control circuitry 110, and read/write circuits 128. In other embodiments, a two dimensional array of memory cells can be used. Memory structure 126 is addressable by word lines via a row decoder 124 and by bit lines via a column decoder 132. The read/write circuits 128 include multiple sense blocks 150 including SB1, SB2, . . . , SBp (sensing circuitry) and allow a page of memory cells to be read or programmed in parallel. In some systems, a Controller 122 is included in the same memory device 100 (e.g., a removable storage card) as the one or more memory die 108. However, in other systems, the Controller can be separated from the memory die 108. In some embodiments the Controller will be on a different die than the memory die. In some embodiments, one Controller 122 will communicate with multiple memory die 108. In other embodiments, each memory die 108 has its own Controller. Commands and data are transferred between the host 140 and Controller 122 via a data bus 120, and between Controller 122 and the one or more memory die 108 via lines 118. In one embodiment, memory die 108 includes a set of input and/or output (I/O) pins that connect to lines 118. Memory structure 126 may comprise one or more monolithic three dimensional arrays of non-volatile memory cells as described above.

Control circuitry 110 cooperates with the read/write circuits 128 to perform memory operations (e.g., erase, program, read, and others) on memory structure 126, and includes a state machine 112, an on-chip address decoder 114, a power control module 116 and a temperature detection circuit 116. The state machine 112 provides die-level control of memory operations. Temperature detection circuit 113 (which is on memory die 108) is configured to detect temperature at the memory structure 126, and can be any suitable temperature detection circuit known in the art. In one embodiment, state machine 112 is programmable by the software. In other embodiments, state machine 112 does not use software and is completely implemented in hardware (e.g., electrical circuits). In one embodiment, control circuitry 110 includes registers, ROM fuses and other storage devices for storing default values such as base voltages and other parameters.

The on-chip address decoder 114 provides an address interface between addresses used by host 140 or Controller 122 to the hardware address used by the decoders 124 and 132. Power control module 116 controls the power and voltages supplied to the word lines and bit lines during memory operations. It can include drivers for word line layers (discussed below) in a 3D configuration, select transistors (e.g., SGS and SGD transistors, described below) and source lines. Power control module 116 may include charge pumps for creating voltages. The sense blocks include bit line drivers. An SGS transistor is a select gate transistor at a source end of a NAND string, and an SGD transistor is a select gate transistor at a drain end of a NAND string.

Any one or any combination of control circuitry 110, state machine 112, decoders 114/124/132, temperature detection circuit 113, power control module 116, sense blocks 150, read/write circuits 128, and Controller 122 can be considered one or more control circuits (or a managing circuit) that performs the functions described herein.

The (on-chip or off-chip) Controller 122 (which in one embodiment is an electrical circuit) may comprise one or more processors 122c, ROM 122a, RAM 122b and a Memory Interface 122d, all of which are interconnected. One or more processors 122c is one example of a control circuit. Other embodiments can use state machines or other custom circuits designed to perform one or more functions. The storage devices (ROM 122a, RAM 122b) comprises code such as a set of instructions, and the processor 122c is operable to execute the set of instructions to provide the functionality described herein. Alternatively or additionally, processor 122c can access code from a storage device in the memory structure, such as a reserved area of memory cells connected to one or more word lines. Memory interface 122d, in communication with ROM 122a, RAM 122b and processor 122c, is an electrical circuit (electrical interface) that provides an electrical interface between Controller 122 and one or more memory die 108. For example, memory interface 122d can change the format or timing of signals, provide a buffer, isolate from surges, latch I/O, etc. Processor 122c can issue commands to control circuitry 110 (or any other component of memory die 108) via Memory Interface 122d.

One embodiment includes a non-volatile storage apparatus, comprising: a plurality of insulator layers including a first insulator layer having a first insulator thickness positioned below a second insulator layer having a second insulator thickness, the first insulator thickness is larger than the second insulator thickness; a plurality of word line layers arranged alternatingly with the plurality of insulator layers in a stack, the plurality of word line layers including a first word line layer having a first word line thickness positioned below a second word line layer having a first word line thickness, the first word line thickness is smaller than the second word line thickness; and a first memory column extending vertically through at least a portion of the stack.

One embodiment includes a non-volatile memory apparatus, comprising: a substrate; a three dimensional monolithic memory array comprising a plurality of conductor layers arranged alternatingly with a plurality of insulator layers in a stack over the substrate to form groups of adjacent conductor layers and insulator layers, each group includes one conductor layer adjacent one insulator layer, the memory array further comprises memory holes extending vertically through at least a portion of the stack, the memory holes have diameters that decreases from an upper region of the stack to a lower region of the stack; and a control circuit above the substrate and connected to the memory array. Each of the groups of adjacent conductor layers and insulator layers has a conductor thickness, an insulator thickness and a total thickness that is a sum of its respective conductor thickness and insulator thickness. Total thickness for the groups of adjacent conductor layers and insulator layers is constant but conductor thickness and insulator thickness vary among at least a subset of the groups.

One embodiment includes a non-volatile memory apparatus, comprising: a plurality of dielectric layers including a first set of dielectric layers having a first dielectric thickness and a second set of dielectric layers having a second dielectric thickness, the second set of dielectric layers is formed above the first set dielectric layers, the first dielectric thickness is larger than the second dielectric thickness; and a plurality of word line layers arranged alternatingly with the plurality of dielectric layers in a stack, the plurality of word line layers include a first set of word line layers having a first word line thickness and a second set of word line layers having a second word line thickness, the second set of word line layers is formed above the first set of word line layers, the first word line thickness is smaller than the second word line thickness.

One embodiment includes a method, comprising: forming a plurality of dielectric layers including a first set of dielectric layers having a first dielectric thickness and a second set of dielectric layers having a second dielectric thickness, the second set of dielectric layers is formed above the first set dielectric layers, the first dielectric thickness is larger than the second dielectric thickness; forming a plurality of word line layers arranged alternatingly with the plurality of dielectric layers in a stack, the plurality of word line layers include a first set of word line layers having a first word line thickness and a second set of word line layers having a second word line thickness, the second set of word line layers is formed above the first set of word line layers, the first word line thickness is smaller than the second word line thickness; and forming a first memory hole extending vertically through at least a portion of the stack, the memory hole having a diameter that decreases from an upper region of the stack to a lower region of the stack.

One embodiment includes a non-volatile memory apparatus, comprising: a plurality of word line layers including a first set of word line layers and a second set of word line layers, the second set of word line layers is formed above the first set of word line layers, the first set of word line layers each have a first word line thickness, the second set of word line layers have word line thicknesses greater than the first word line thickness; and a first memory column extending vertically through at least a portion of the plurality of word line layers.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. A non-volatile storage apparatus, comprising:
a plurality of insulator layers including a first insulator layer having a first insulator thickness positioned below a second insulator layer having a second insulator thickness, the first insulator thickness is larger than the second insulator thickness;
a plurality of word line layers arranged alternatingly with the plurality of insulator layers in a stack, the plurality of word line layers including a first word line layer having a first word line thickness positioned below a second word line layer having a first word line thickness, the first word line thickness is smaller than the second word line thickness; and
a first memory column extending vertically through at least a portion of the stack.

2. The non-volatile storage apparatus of claim 1, wherein:
the first memory column has a diameter that decreases from an upper region of the stack to a lower region of the stack.

3. The non-volatile storage apparatus of claim 1, wherein:
the first insulator layer is positioned adjacent to the first word line layer;
the second insulator layer is positioned adjacent to the second word line layer;
the sum of the first word line thickness and the first insulator thickness is equal to the sum of the second word line thickness and the second insulator thickness.

4. The non-volatile memory apparatus of claim 1, further comprising:
a substrate, the stack is positioned over the substrate.

5. The non-volatile storage apparatus of claim 1, wherein:
the first word line layer is separated from the second word line layer by other word line layers.

6. The non-volatile storage apparatus of claim 1, wherein:
the first word line layer is an adjacent word line layer to the second word line layer and the first insulator layer is between the first word line layer and the second word line layer.

7. A non-volatile memory apparatus, comprising:
a substrate;
a three dimensional monolithic memory array comprising a plurality of conductor layers arranged alternatingly with a plurality of insulator layers in a stack over the substrate to form groups of adjacent conductor layers and insulator layers, each group includes one conductor layer adjacent one insulator layer, the memory array further comprises memory holes extending vertically through at least a portion of the stack, the memory holes have diameters that decreases from an upper region of the stack to a lower region of the stack; and
a control circuit above the substrate and connected to the memory array;
each of the groups of adjacent conductor layers and insulator layers has a conductor thickness, an insulator thickness and a total thickness that is a sum of its respective conductor thickness and insulator thickness;
total thickness for the groups of adjacent conductor layers and insulator layers is constant but conductor thickness and insulator thickness vary among at least a subset of the groups.

8. The non-volatile storage apparatus of claim 7, wherein:
the memory holes form a plurality of NAND strings in communication with the plurality of conductor layers.

9. The non-volatile storage apparatus of claim 7, wherein:
the groups of adjacent conductor layers and insulator layers comprise a first set of groups of adjacent conductor layers and insulator layers and a second set of groups of adjacent conductor layers and insulator layers;
the first set of groups of adjacent conductor layers and insulator layers are positioned below the second set of groups of adjacent conductor layers and insulator layers;
the first set of groups of adjacent conductor layers and insulator layers each have a first conductor thickness;
the second set of groups of adjacent conductor layers and insulator layers each have a second conductor thickness; and
the first conductor thickness is smaller than the second conductor thickness.

10. The non-volatile storage apparatus of claim 7, wherein:
the groups of adjacent conductor layers and insulator layers comprise a first set of groups of adjacent conductor layers and insulator layers and a second set of groups of adjacent conductor layers and insulator layers;
the first set of groups of adjacent conductor layers and insulator layers are positioned below the second set of groups of adjacent conductor layers and insulator layers;
the first set of groups of adjacent conductor layers and insulator layers each have a first conductor thickness;
the second set of groups of adjacent conductor layers and insulator layers have conductor thicknesses greater than the first conductor thickness.

11. A non-volatile memory apparatus, comprising:
a plurality of dielectric layers including a first set of dielectric layers having a first dielectric thickness and a second set of dielectric layers having a second dielectric thickness, the second set of dielectric layers is formed above the first set dielectric layers, the first dielectric thickness is larger than the second dielectric thickness; and
a plurality of word line layers arranged alternatingly with the plurality of dielectric layers in a stack, the plurality of word line layers include a first set of word line layers having a first word line thickness and a second set of word line layers having a second word line thickness, the second set of word line layers is formed above the first set of word line layers, the first word line thickness is smaller than the second word line thickness.

12. The non-volatile storage apparatus of claim 11, further comprising:
a memory hole extending vertically through at least a portion of the stack, the memory hole has a diameter that decreases from an upper region of the stack to a lower region of the stack.

13. The non-volatile storage apparatus of claim 11, wherein:
the first dielectric layer is positioned adjacent to the first word line layer;
the second dielectric layer is positioned adjacent to the second word line layer;
the sum of the first word line thickness and the first dielectric thickness is equal to the sum of the second word line thickness and the second dielectric thickness.

14. The non-volatile memory apparatus of claim 11, further comprising:
a substrate, the stack is positioned over the substrate.

15. The non-volatile storage apparatus of claim 11, wherein:
the second set of word line layers are consecutive word line layers.

16. The non-volatile storage apparatus of claim 11, wherein:
the plurality of word line layers include a third set of word line layers having a third word line thickness that is smaller than the first word line thickness; and
the third set of word line layers are intermixed with the second set of word line layers.

17. A method, comprising:
forming a plurality of dielectric layers including a first set of dielectric layers having a first dielectric thickness and a second set of dielectric layers having a second dielectric thickness, the second set of dielectric layers is formed above the first set dielectric layers, the first dielectric thickness is larger than the second dielectric thickness;
forming a plurality of word line layers arranged alternatingly with the plurality of dielectric layers in a stack, the plurality of word line layers include a first set of word line layers having a first word line thickness and a second set of word line layers having a second word line thickness, the second set of word line layers is formed above the first set of word line layers, the first word line thickness is smaller than the second word line thickness; and
forming a first memory hole extending vertically through at least a portion of the stack, the memory hole having a diameter that decreases from an upper region of the stack to a lower region of the stack.

18. The method of claim 17, wherein the forming the plurality of dielectric layers and the forming the plurality of word line layers comprises:
depositing alternating dielectric layers and sacrificial layers, the sacrificial layers are deposited with smaller thicknesses on bottom and larger thicknesses on top;
removing the sacrificial layers from between the dielectric layers to create recessed regions; and
filling in the recessed regions with gate material.

19. The method of claim 17, wherein the forming the plurality of dielectric layers and the forming the plurality of word line layers comprises:
depositing alternating silicon oxide layers and silicon nitride layers, the silicon nitride layers are deposited with smaller thicknesses on bottom and larger thicknesses on top;
removing the silicon nitride layers from between the silicon oxide layers to create recessed regions; and
filling in the recessed regions with Tungsten.

20. The method of claim 17, wherein the forming the plurality of dielectric layers and the forming the plurality of word line layers comprises:
depositing groups of adjacent dielectric layers and sacrificial layers, each group includes one sacrificial layer adjacent one dielectric layer, each of the groups of adjacent dielectric layers and sacrificial layers has a sacrificial layer line thickness and a dielectric thickness and a total thickness that is a sum of its respective sacrificial layer thickness and dielectric thickness, total thickness for the groups of adjacent dielectric layers and sacrificial layers is constant but sacrificial layer thickness and dielectric thickness vary among at least a subset of the groups;
removing the sacrificial layers from between the dielectric layers to create recessed regions; and
filling in the recessed regions with gate material to form the first set of word line layers having the first word line thickness and the second set of word line layers having the second word line thickness.

21. A non-volatile memory apparatus, comprising:
a plurality of word line layers including a first set of word line layers and a second set of word line layers, the second set of word line layers is formed above the first set of word line layers, the first set of word line layers each have a first word line thickness, the second set of word line layers have word line thicknesses greater than the first word line thickness; and
a first memory column extending vertically through at least a portion of the plurality of word line layers.

22. The non-volatile memory apparatus of claim 21, further comprising:
a substrate; and
a plurality of dielectric layers arranged alternatingly with the plurality of word line layers in a stack over the substrate, the memory column extends vertically through at least a portion of the stack, the first memory column has a diameter that decreases from an upper region of the stack to a lower region of the stack.

23. The non-volatile memory apparatus of claim 21, further comprising:
a plurality of memory columns extending through the stack and including the first memory column, the plurality of memory columns have diameters which are progressively smaller closer to a bottom of the stack, the memory columns extend at least from a top word line layer of the plurality of word line layers to a bottom word line layer of the plurality of word line layers;
wherein the plurality of memory columns form a plurality of NAND strings arranged along the memory columns, the NAND strings comprise a plurality of memory cells in communication with the plurality of word line layers;
wherein the plurality of memory holes and the plurality of word line layers comprise a non-volatile memory array arranged in a three dimensional structure.
